(19) United States
(12) Patent Application Publication
(10) Pub. No.: US 2025/0283935 A1
(43) Pub. Date: Sep. 11, 2025

(54) DISPLAY APPARATUS AND ELECTRONIC DEVICE

(71) Applicant: Samsung Display Co., Ltd., Yongin-Si (KR)

(72) Inventor: Changjin Im, Yongin-si (KR)

(21) Appl. No.: 19/050,121

(22) Filed: Feb. 11, 2025

(30) Foreign Application Priority Data
Mar. 8, 2024 (KR) 10-2024-0033322

(51) Int. Cl. G01R 31/28; H01L 23/498; H05K 1/02; H10K 59/131; H10K 59/95

(52) U.S. Cl. CPC G01R 31/2818; H01L 23/49838; H05K 1/0268; H10K 59/131; H10K 59/95

(57) ABSTRACT

A display apparatus includes a display panel including a panel test pad portion, a printed circuit board including a PCB test pad portion and test terminals, and a flexible circuit board including a first transmission pad portion electrically connected to the panel test pad portion and a second transmission pad portion electrically connected to the PCB test pad portion, wherein the panel test pad portion includes first to third panel pads, the PCB test pad portion includes a first PCB pad electrically connected to the first panel pad, second and third PCB pads electrically connected to the second panel pad, and a fourth PCB pad electrically connected to the third panel pad, and the test terminals include first and second input terminals respectively electrically connected to the first and second PCB pads, and first to third measurement terminals respectively electrically connected to the second to fourth PCB pads.

### CROSS-REFERENCE TO RELATED APPLICATION

This application is based on and claims priority under 35 U.S.C. § 119 to Korean Patent Application No. 10-2024-0033322, filed on Mar. 8, 2024, in the Korean Intellectual Property Office, the disclosure of which is incorporated by reference herein in its entirety.

### BACKGROUND

### Field

One or more embodiments disclosed herein relate to a display apparatus, and more particularly, to a display apparatus that may facilitate checking of the bonding state between a display panel and a flexible circuit board and the bonding state between a flexible circuit board and a printed circuit board.

### Description of the Related Art

A display apparatus may include a display panel, a flexible circuit board, and a printed circuit board, and the printed circuit board may be electrically connected to the display panel through the flexible circuit board. To this end, a pad on the flexible circuit board may be bonded to a pad on the display panel, and another pad on the flexible circuit board may be bonded to a pad on the printed circuit board. As the resolution of display apparatuses increases, the size and the pitch of such pads decrease, and bonding of the printed circuit board, flexible circuit board, and display panel may require more precise positioning. The bonding quality between the flexible circuit board and the display panel and the bonding quality between the flexible circuit board and the printed circuit board may greatly affect whether electrical signals are accurately transmitted to the display panel. Therefore, the quality of the bonding between the flexible circuit board and the display panel and the bonding between the flexible circuit board and the printed circuit board may need to be tested.

### SUMMARY

One or more embodiments disclosed herein may include a display apparatus that facilitates checking of the state of the bond between a flexible circuit board and a display panel and the state of the bond between the flexible circuit board and a printed circuit board. Additional aspects are set forth in part in the description which follows and, in part, will be apparent from the description, or may be learned by practice of the presented embodiments of the disclosure. Embodiments set forth herein are merely some examples, and embodiments of the disclosure are not limited to these examples.

According to one or more embodiments, a display apparatus includes a display panel including a panel test pad portion, a printed circuit board including a printed circuit board (PCB) test pad portion and test terminals, and a flexible circuit board including a first transmission pad portion electrically connected to the panel test pad portion and a second transmission pad portion electrically connected to the PCB test pad portion, wherein the panel test pad portion includes a first panel pad, a second panel pad, and a third panel pad, the PCB test pad portion includes a first PCB pad electrically connected to the first panel pad, a second PCB pad electrically connected to the second panel pad, a third PCB pad electrically connected to the second panel pad, and a fourth PCB pad electrically connected to the third panel pad, and the test terminals include a first input terminal electrically connected to the first PCB pad, a second input terminal electrically connected to the second PCB pad, a first measurement terminal electrically connected to the second PCB pad, a second measurement terminal electrically connected to the third PCB pad, and a third measurement terminal electrically connected to the fourth PCB pad.

When a test current is applied to the first input terminal, the first PCB pad, the test current may flow through a current path including the first panel pad, the second panel pad, and the second PCB pad.

The first transmission pad portion may include a 1st-1 transmission pad overlapping the first panel pad, a 1st-2 transmission pad overlapping the second panel pad, and a 1st-3 transmission pad overlapping the third panel pad, and the second transmission pad portion may include a 2nd-1 transmission pad overlapping the first PCB pad, a 2nd-2 transmission pad overlapping the second PCB pad, a 2nd-3 transmission pad overlapping the third PCB pad, and a 2nd-4 transmission pad overlapping the fourth PCB pad, wherein the 2nd-1 transmission pad may be electrically connected to the 1st-1 transmission pad by a first wiring line, the 2nd-2 transmission pad may be electrically connected to the 1st-2 transmission pad by a second wiring line, the 2nd-3 transmission pad may be electrically connected to the 1st-2 transmission pad by the second wiring line and a sub-wiring line connected to the second wiring line, and the 2nd-4 transmission pad may be electrically connected to the 1st-3 transmission pad by a third wiring line.

The display apparatus may further include an integrated circuit chip including an integrated circuit (IC) test pad portion, wherein the display panel may further include an IC transmission pad portion electrically connected to the IC test pad portion, and the IC test pad portion may include a first IC test pad, a second IC test pad, and a third IC test pad, wherein the first IC test pad may be electrically connected to the first panel pad, and the second IC test pad may be electrically connected to the second panel pad.

When a test current is applied to the first input terminal, the test current may flow through a current path including the first PCB pad, the first panel pad, the first IC test pad, the second IC test pad, the second panel pad, and the second PCB pad.

The IC transmission pad portion may include a first IC transmission pad overlapping the first IC test pad, a second IC transmission pad overlapping the second IC test pad, and a third IC transmission pad overlapping the third IC test pad, and the panel test pad portion may further include a fourth panel pad and a fifth panel pad, wherein the first panel pad may be electrically connected to the first IC transmission pad by a first panel wiring line, the second panel pad may be electrically connected to the second IC transmission pad by a second panel wiring line, the third panel pad may be electrically connected to the second IC transmission pad by the second panel pad and a third panel wiring line that electrically connects the second panel pad to the third panel pad, the fourth panel pad may be electrically connected to the second IC transmission pad by a fourth panel wiring line, and the fifth panel pad may be electrically connected to the third IC transmission pad by a fifth panel wiring line.

The PCB test pad portion may further include a fifth PCB pad electrically connected to the fourth panel pad and a sixth PCB pad electrically connected to the fifth panel pad, and the test terminals may further include a fourth measurement terminal electrically connected to the fifth PCB pad and a fifth measurement terminal electrically connected to the sixth PCB pad.

A plurality of panel test pad portions may be provided, a plurality of PCB test pad portions may be provided, and a plurality of flexible circuit boards may be provided, wherein the plurality of flexible circuit boards may be respectively located to correspond to the plurality of panel test pad portions and correspond to the plurality of PCB test pad portions.

The first input terminal may be electrically connected to the first PCB pad of one PCB test pad portion among the plurality of PCB test pad portions by a first PCB wiring line, and the second input terminal may be electrically connected to the first PCB pad of another PCB test pad portion among the plurality of PCB test pad portions by a second PCB wiring line.

A plurality of first measurement terminals, a plurality of second measurement terminals, and a plurality of third measurement terminals, which are respectively and electrically connected to the plurality of PCB test pad portions, may be provided.

According to one or more embodiments, a display apparatus includes a display panel including a panel test pad portion, a printed circuit board including a printed circuit board (PCB) test pad portion and test terminals, and a flexible circuit board including a first transmission pad portion electrically connected to the panel test pad portion and a second transmission pad portion electrically connected to the PCB test pad portion, wherein the panel test pad portion includes a first panel pad and a second panel pad, the first transmission pad portion includes a 1st-1 transmission pad overlapping the first panel pad and a 1st-2 transmission pad overlapping the second panel pad, the second transmission pad portion includes a 2nd-1 transmission pad electrically connected to the 1st-1 transmission pad by a first wiring line, a 2nd-2 transmission pad electrically connected to the 1st-2 transmission pad by a second wiring line, and a 2nd-3 transmission pad electrically connected to the 1st-2 transmission pad by the second wiring line and a sub-wiring line connected to the second wiring line, the PCB test pad portion includes a first PCB pad overlapping the 2nd-1 transmission pad, a second PCB pad overlapping the 2nd-2 transmission pad, and a third PCB pad overlapping the 2nd-3 transmission pad, and the test terminals include a first input terminal electrically connected to the first PCB pad, a second input terminal electrically connected to the second PCB pad, a first measurement terminal electrically connected to the second PCB pad, and a second measurement terminal electrically connected to the third PCB pad.

When a test current is applied to the first input terminal, the test current may flow through a current path including the first PCB pad, the first panel pad, the second panel pad, and the second PCB pad.

The panel test pad portion may further include a third panel pad electrically connected to the first panel pad and the second panel pad, the PCB test pad portion may further include a fourth PCB pad electrically connected to the third panel pad, and the test terminals may further include a third measurement terminal electrically connected to the fourth PCB pad.

According to one or more embodiments, a display apparatus includes a display panel including a first panel test pad portion and a second panel test pad portion, a printed circuit board including a first PCB test pad portion, a second PCB test pad portion, and test terminals, and a first flexible circuit board having one end connected to the first panel test pad portion and an opposite end connected to the first PCB test pad portion and a second flexible circuit board having one end connected to the second panel test pad portion and an opposite end connected to the second PCB test pad portion, wherein each of the first PCB test pad portion and the second PCB test pad portion includes a first PCB pad group and a second PCB pad group, each of the first PCB pad group and the second PCB pad group includes a first PCB pad, a second PCB pad, a third PCB pad, and a fourth PCB pad, and the test terminals include a first input terminal electrically connected to the first PCB pad of the first PCB pad group of the first PCB test pad portion, a second input terminal electrically connected to the first PCB pad of the second PCB pad group of the second PCB test pad portion, a first measurement terminal portion electrically connected to the first PCB test pad portion, and a second measurement terminal portion electrically connected to the second PCB test pad portion, wherein each of the first measurement terminal portion and the second measurement terminal portion includes a 1st-1 measurement terminal electrically connected to the second PCB pad of the first PCB pad group, a 2nd-1 measurement terminal electrically connected to the third PCB pad of the first PCB pad group, a 3rd-1 measurement terminal electrically connected to the fourth PCB pad of the first PCB pad group, a 1st-2 measurement terminal electrically connected to the second PCB pad of the second PCB pad group, a 2nd-2 measurement terminal electrically connected to the third PCB pad of the second PCB pad group, and a 3rd-2 measurement terminal electrically connected to the fourth PCB pad of the second PCB pad group.

The second PCB pad of the first PCB pad group of the first PCB test pad portion may be electrically connected to the second PCB pad of the second PCB pad group of the first PCB test pad portion, the first PCB pad of the first PCB pad group of the second PCB test pad portion may be electrically connected to the first PCB pad of the second PCB pad group of the first PCB test pad portion, and the second PCB pad of the first PCB pad group of the second PCB test pad portion may be electrically connected to the second PCB pad of the second PCB pad group of the second PCB test pad portion.

The first panel test pad portion may include a first panel pad, a second panel pad, and a third panel pad, the first PCB pad of the first PCB pad group of the first PCB test pad portion may be electrically connected to the first panel pad, the second PCB pad of the first PCB pad group of the first PCB test pad portion may be electrically connected to the second panel pad, the third PCB pad of the first PCB pad group of the first PCB test pad portion may be electrically connected to the second panel pad, and the fourth PCB pad of the first PCB pad group of the first PCB test pad portion may be electrically connected to the third panel pad.

When a test current is applied to the first input terminal, the test current may flow through a current path including the first PCB pad of the first PCB pad group of the first PCB test pad portion, the first panel pad, the second panel pad, and the second PCB pad of the first PCB pad group of the first PCB test pad portion.

The first flexible circuit board may include a first transmission pad portion connected to the first panel test pad portion and a second transmission pad portion connected to the first PCB test pad portion, wherein the first transmission pad portion may include a 1st-1 transmission pad overlapping the first panel pad, a 1st-2 transmission pad overlapping the second panel pad, and a 1st-3 transmission pad overlapping the third panel pad, and the second transmission pad portion may include a 2nd-1 transmission pad, a 2nd-2 transmission pad, a 2nd-3 transmission pad, and a 2nd-4 transmission pad, which respectively overlap the first PCB pad, the second PCB pad, the third PCB pad, and the fourth PCB pad of the first PCB pad group of the first PCB test pad portion, wherein the 1st-1 transmission pad and the 2nd-1 transmission pad may be electrically connected to each other by a first wiring line, the 1st-2 transmission pad and the 2nd-2 transmission pad may be electrically connected to each other by a second wiring line, the 1st-2 transmission pad and the 2nd-3 transmission pad may be electrically connected to each other by the second wiring line and a sub-wiring line connected to the second wiring line, and the 1st-3 transmission pad and the 2nd-4 transmission pad may be electrically connected to each other by a third wiring line.

The display apparatus may further include an integrated circuit chip including an IC test pad portion, wherein the display panel may further include an IC transmission pad portion electrically connected to the IC test pad portion, and the IC test pad portion may include a first IC test pad, a second IC test pad, and a third IC test pad, wherein the first IC test pad may be electrically connected to the first panel pad, and the second IC test pad may be electrically connected to the second panel pad.

When a test current is applied to the first input terminal, the first PCB pad of the first PCB pad group of the first PCB test pad portion, the test current may flow through a current path including the first panel pad, the first IC test pad, the second IC test pad, the second panel pad, and the second PCB pad of the first PCB pad group of the first PCB test pad portion.

According to one or more embodiments, an electronic device includes, a display apparatus, and a housing accommodating the display apparatus, wherein the display apparatus may include a display panel including a panel test pad portion, a printed circuit board including a printed circuit board test pad portion and test terminals, and a flexible circuit board including a first transmission pad portion electrically connected to the panel test pad portion and a second transmission pad portion electrically connected to the PCB test pad portion, wherein the panel test pad portion may include a first panel pad, a second panel pad, and a third panel pad, the PCB test pad portion may include a first PCB pad electrically connected to the first panel pad, a second PCB pad electrically connected to the second panel pad, a third PCB pad electrically connected to the second panel pad, and a fourth PCB pad electrically connected to the third panel pad, and the test terminals may include a first input terminal electrically connected to the first PCB pad, a second input terminal electrically connected to the second PCB pad, a first measurement terminal electrically connected to the second PCB pad, a second measurement terminal electrically connected to the third PCB pad, and a third measurement terminal electrically connected to the fourth PCB pad.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1A is a schematic plan view of a display apparatus according to an embodiment;

FIG. 1B is a schematic plan view of a display apparatus according to an embodiment;

FIG. 2 is an enlarged view of an area ‘A’ of FIG. 1A according to an embodiment;

FIG. 3 is an enlarged view of the area ‘A’ of FIG. 1A excluding a flexible circuit board and an integrated circuit chip, according to an embodiment;

FIG. 4 is a perspective view illustrating structures in current paths used during connection resistance measurement according to the embodiment of FIGS. 2 and 3;

FIG. 5 is an enlarged view of the area ‘A’ of FIG. 1A according to an embodiment;

FIG. 6 is an enlarged view of the area ‘A’ of FIG. 1A excluding a flexible circuit board and an integrated circuit chip, according to an embodiment;

FIG. 7 is a perspective view illustrating structures in current paths used during connection resistance measurement according to the embodiment of FIGS. 5 and 6;

FIG. 8 is an enlarged view of an area ‘B’ of FIG. 1B according to an embodiment;

FIG. 9 is an enlarged view of an area ‘B’ corresponding to a first flexible circuit board and a second flexible circuit board in FIG. 8, according to an embodiment;

FIG. 10 is an enlarged view of FIG. 9 excluding a flexible circuit board and an integrated circuit chip;

FIG. 11 is a perspective view illustrating structures in current paths used during connection resistance measurement according to the embodiment of FIGS. 8 to 10;

FIG. 12 is an enlarged view of the area ‘B’ of FIG. 1B according to an embodiment;

FIG. 13 is an enlarged view of an area corresponding to a first flexible circuit board and a second flexible circuit board in FIG. 12, according to an embodiment;

FIG. 14 is an enlarged view of FIG. 13 excluding a flexible circuit board and an integrated circuit chip;

FIG. 15 is a perspective view illustrating structures in current paths used during connection resistance measurement according to the embodiment of FIGS. 12 to 14; and

FIG. 16 is a schematic cross-sectional view within a display area of a display apparatus according to an embodiment.

### DETAILED DESCRIPTION

Reference will now be made in detail to embodiments, examples of which are illustrated in the accompanying drawings. In this regard, the present embodiments may have different forms and should not be construed as being limited to the descriptions set forth herein. Accordingly, the embodiments are merely described below, by referring to the figures, to explain aspects of the present description.

The disclosure may include various embodiments and modifications, and embodiments thereof will be illustrated in the drawings and will be described herein in detail. The effects and features of the disclosure and the accompanying methods thereof will become apparent from the following description of the embodiments, taken in conjunction with the accompanying drawings. However, the disclosure is not limited to the embodiments described below and may be embodied in various modes.

In the present specification, the terms “first,” “second,” etc. may be used to describe various elements, but these elements should not be limited by these terms. These terms are only used to distinguish one component from another component.

As used herein, the singular forms “a,” “an,” and “the” are intended to include the plural forms as well unless the context clearly indicates otherwise.

In the present specification, the terms “includes”, “including”, “has”, and/or “having” specify the presence of stated features or elements but do not preclude the presence or addition of one or more other features or elements.

In the present specification, an expression such as “A and/or B” indicates A, B, or A and B. As used herein, the term “and/or” includes any and all combinations of one or more of the associated listed items. Also, an expression such as “at least one of A and B” indicates A, B, or A and B. Throughout the disclosure, the expression “at least one of a, b or c” indicates only a, only b, only c, both a and b, both a and c, both b and c, all of a, b, and c, or variations thereof.

In the present specification, an element, such as a film, a layer, a region, or a board, referred to as being “on” or “formed on” another element may be directly or indirectly on or formed on the other element. That is, for example, an intervening film, layer, region, or board may be present.

In the present specification, a layer, region, or element referred to as being “connected” means that the layer, the region, or the element may be directly connected or may be indirectly connected with intervening layers, regions, or elements therebetween. For example, a layer, region, or element referred to as being “electrically connected to” or “electrically coupled to” another layer, region, or element may be directly or indirectly electrically connected or coupled to the other layer, region, or element. That is, for example, intervening layers, regions, or elements may be present therebetween.

In the present specification, the x-axis, y-axis, and z-axis are not limited to the three axes in an orthogonal coordinate system and may be interpreted in a broad sense including these. For example, the x-axis, y-axis, and z-axis may refer to different directions that are orthogonal to each other or may refer to different directions that are not orthogonal to each other.

In the present specification, specific embodiments of processes may be described and related, but embodiments of this disclosure may not be limited to a specific process order and may be performed in an order that is different from the described order. For example, two consecutively described processes may be performed substantially at the same time or performed in an order opposite to the described order.

In the present specification, “in a plan view” means the subject part is viewed from above That is, in the present specification, “in a plan view” may mean “when viewed in a direction perpendicular to a display panel.”

Hereinafter, embodiments of the disclosure are described in detail with reference to the accompanying drawings, and in descriptions referring to the drawings, the same reference numerals will be given to the same or corresponding components. Sizes of elements in the drawings may be exaggerated or contracted for convenience of description. In other words, because sizes and thicknesses of elements in the drawings are illustrated for convenience of description, the following embodiments are not limited thereto.

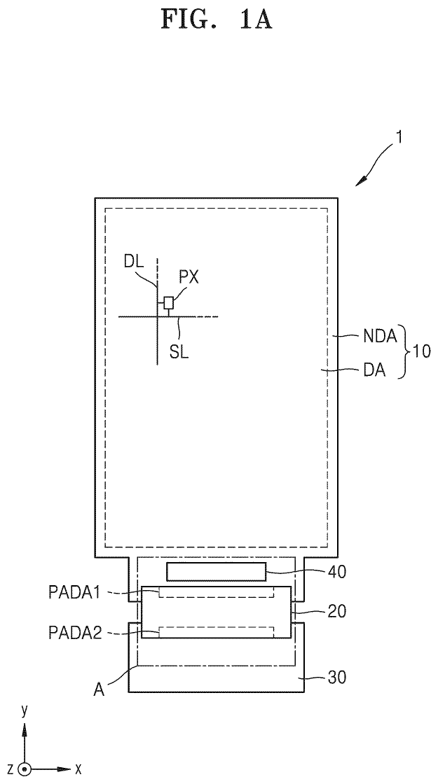

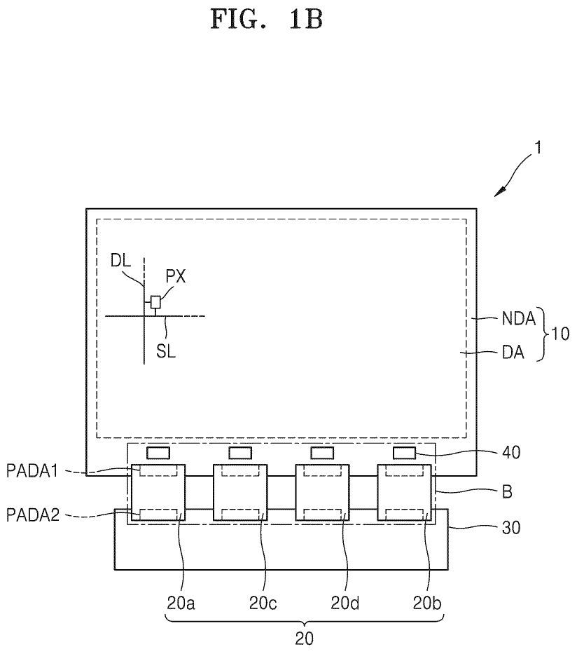

FIGS. 1A and 1B are schematic plan views of a display apparatus 1.

Referring to FIGS. 1A and 1B, the display apparatus 1 may include a display panel 10, a flexible circuit board 20, and a printed circuit board 30. The display apparatus 1 may further include an integrated circuit chip 40.

The display panel 10 may include a display area DA and a non-display area NDA. The display area DA may be an area where a plurality of pixels PX display images. Signal lines, such as a scan line SL and/or a data line DL, may be arranged in the display area DA. Each of the pixels PX may include sub-pixels, and the sub-pixels may emit light having a certain color by using a light-emitting diode as a display element. For example, each light-emitting diode may emit red, green, or blue light. Each light-emitting diode may be connected to a pixel circuit including a thin-film transistor and a storage capacitor.

The non-display area NDA may be an area that does not provide images. The non-display area NDA may surround the display area DA.

A driver for providing electrical signals to the pixels PX and/or a power line for providing power may be in the non-display area NDA. For example, a scan driver that provides a scan signal to each pixel PX through the scan line SL, and/or a data driver that provides a data signal to each pixel PX through the data line DL may be in the non-display area NDA. In an embodiment, the data driver may have the same form as the integrated circuit chip 40.

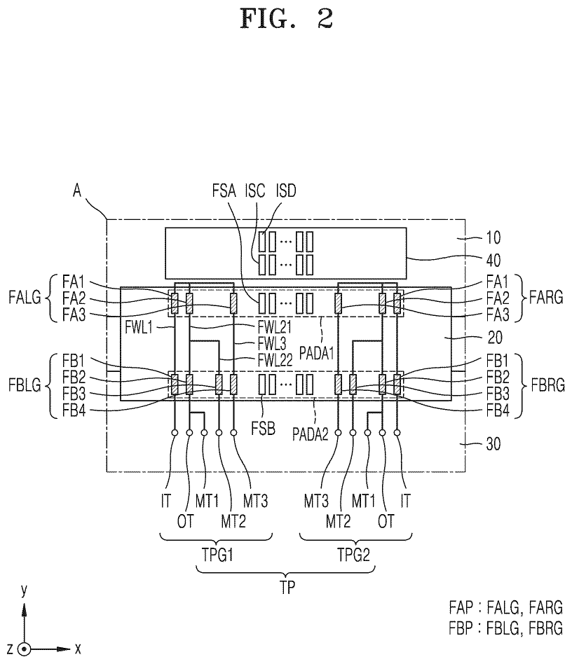

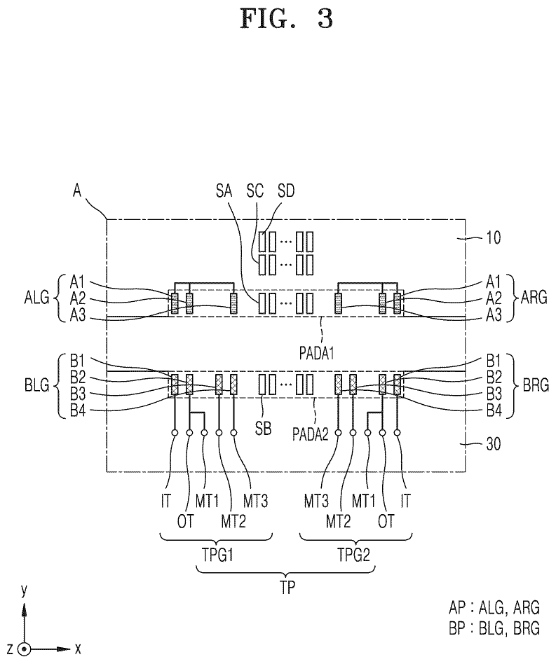

The display panel 10 may include a first pad area PADA1 including a plurality of pads. The first pad area PADA1 may be in the non-display area NDA. The first pad area PADA1 may be an area containing a plurality of pads electrically connecting the display panel 10 to the flexible circuit board 20. One end of the flexible circuit board 20 may be on the first pad area PADA1 of the display panel 10. For example, a plurality of pads disposed at one end of the flexible circuit board 20 may respectively overlap a plurality of pads in the first pad area PADA1 of the display panel 10. For example, in the first pad area PADA1, the display panel 10 may include a panel test pad portion AP (see FIG. 3) and a first panel signal transmission pad SA (see FIG. 3). For example, the flexible circuit board 20 may include a first transmission pad portion FAP (see FIG. 2) and a first signal transmission pad FSA (see FIG. 2) that overlap the first pad area PADA1 of the display panel 10.

The printed circuit board 30 may include a second pad area PADA2 including a plurality of pads. The second pad area PADA2 may be an area containing pads electrically connecting the flexible circuit board 20 to the printed circuit board 30. One end of the flexible circuit board 20 may be disposed on the first pad area PADA1 of the display panel 10, and the other end may be disposed on the second pad area PADA2 of the printed circuit board 30. For example, a plurality of pads disposed on an end of the flexible circuit board 20 opposite the first pad area PADA1 may overlap a plurality of pads in the second pad area PADA2 of the printed circuit board 30. As described further below, the printed circuit board 30 may include a printed circuit board (PCB) test pad portion BP (see FIG. 3) and a PCB output signal pad SB (see FIG. 3) in the second pad area PADA2. The flexible circuit board 20 may include a second transmission pad portion FBP (see FIG. 2) and a second signal transmission pad FSB (see FIG. 2) that overlap the second pad area PADA2 of the printed circuit board 30.

One end of the flexible circuit board 20 may overlap the display panel 10, and the other end of the flexible circuit board 20 may overlap the printed circuit board 30. One end of the flexible circuit board 20 may be connected to the display panel 10, and the other end of the flexible circuit board 20 may be connected to the printed circuit board 30.

In an embodiment, the display apparatus 1 may include one flexible circuit board 20, as shown in FIG. 1A. In this case, the display panel 10 may include one panel test pad portion AP (see FIG. 3) corresponding to the first transmission pad portion FAP of one flexible circuit board 20. In addition, the printed circuit board 30 may include one PCB test pad portion BP (see FIG. 3) corresponding to the second transmission pad portion FBP of one flexible circuit board 20.

In an embodiment, the display apparatus 1 may include a plurality of flexible circuit boards 20, as shown in FIG. 1B. In this case, the display panel 10 may include a plurality of panel test pad portions AP (see FIG. 3), and the printed circuit board 30 may include a plurality of PCB test pad portions BP (see FIG. 3). The plurality of panel test pad portions AP (see FIG. 3) and the plurality of PCB test pad portions BP (see FIG. 3) may be electrically connected to each other by the plurality of flexible circuit boards 20. When the display apparatus 1 includes a plurality of flexible circuit boards 20, a plurality of integrated circuit chips 40 may be provided.

A processor and/or memory, etc. may be located on the printed circuit board 30. For example, when the display apparatus 1 is applied to a mobile communication terminal, the processor may be an application processor including a central processing unit, a graphics processing unit, and/or a modem. The flexible circuit board 20 may be bent, and thus, the printed circuit board 30 may be located on the back of the display panel 10.

FIGS. 1A and 1B show examples where the integrated circuit chip 40 is mounted on the non-display area NDA of the display panel 10. The integrated circuit chip 40 may be mounted on the non-display area NDA of the display panel 10 as a chip on glass (COG) type or may be mounted on the flexible circuit board 20 as a chip on film (COF) type. Hereinafter, for convenience of description, the description below will focus on the integrated circuit chip 40 mounted on the display panel 10. However, the disclosure is not limited thereto. For example, the integrated circuit chip 40 may be mounted on the flexible circuit board 20.

Signals output from the integrated circuit chip 40 may be transmitted to the display panel 10 through an integrated circuit (IC) output signal pad ISD (see FIG. 2) of the integrated circuit chip 40 and an IC input signal pad SD (see FIG. 3) of the display panel 10. In an embodiment, the integrated circuit chip 40 may receive signals from the printed circuit board 30 and may use the signals (e.g., image data and signals related thereto, or power) as the basis for generating data signals. A signal from the printed circuit board 30 may be transmitted to a PCB input signal pad ISC of the integrated circuit chip 40 through the PCB output signal pad SB of the printed circuit board 30, the first and second signal transmission pads FSA and FSB of the flexible circuit board 20, and the first and second panel signal transmission pads SA and SC of the display panel 10.

An electronic device may include the display apparatus 1. For example, the electronic device may include a portable electronic device, such as a mobile phone, a laptop computer, a tablet personal computer (PC), a smartphone, a mobile communication terminal, an electronic notebook, an electronic book, a portable multimedia player (PMP), a navigation device, or an ultra mobile PC (UMPC). For example, the electronic device may include a television, a monitor, a billboard, an electronic device for Internet of things (IoT) or a wearable electronic device, such as a smart watch, a watch phone, a glasses type display, or a head-mounted display (HMD). For example, the electronic device may include a display panel of a vehicle, a center information display (CID) arranged on a center fascia or dashboard of a vehicle, a rearview mirror display replacing a side mirror of a vehicle, or an electronic device for a display arranged on a rear surface of a front seat, as entertainment for a back seat of a vehicle. For example, the electronic device may include a flat panel display, a curved display, a computer monitor, a medical monitor, a television, a billboard, an indoor or outdoor lighting, a signal light, head-up display, a fully or partially transparent display, a flexible display, a rollable display, a foldable display, a stretchable display, a laser printer, a telephone, a mobile phone, a tablet, a phablet, a personal digital assistant (PDA), a wearable device, a laptop computer, a digital camera, a camcorder, a viewfinder, a micro-display, a 3D display, a virtual reality or augmented reality display, a vehicle, a video wall comprising tiled multiple displays, a theater or stadium screen, a phototherapy device, or a signage. According to an embodiment, the electronic device including the display apparatus 1 of FIG. 1a or FIG. 1b may include a lower cover disposed below the display apparatus 1. According to an embodiment, the electronic device may further include a cover window disposed on the display apparatus 1. For example, the lower cover and the cover window may be combined and form an exterior appearance of the electronic device.

FIG. 2 is an enlarged view of an area ‘A’ of FIG. 1A according to an embodiment. FIG. 3 is an enlarged view of an embodiment of the area ‘A’ of FIG. 2 excluding the flexible circuit board 20 and the integrated circuit chip 40.

Referring to FIGS. 2 and 3, the display panel 10 may include a panel test pad portion AP. The printed circuit board 30 may include a PCB test pad portion BP and test terminals TP.

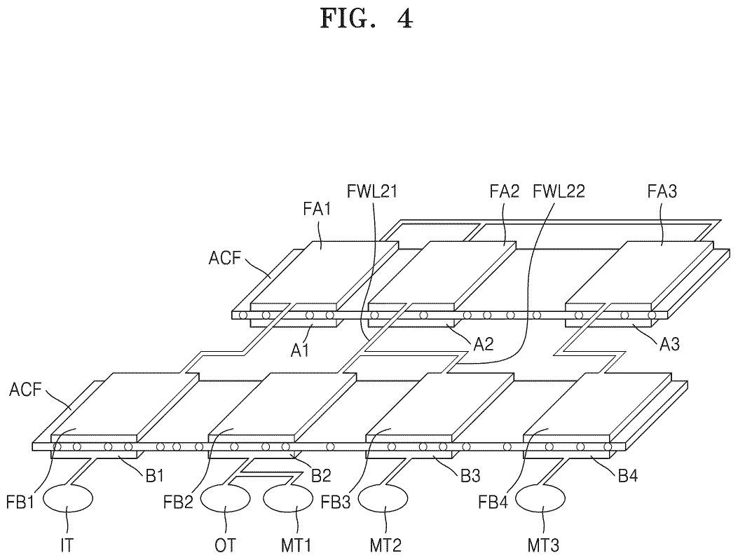

The first transmission pad portion FAP disposed at one end of the flexible circuit board 20 may be electrically connected to the panel test pad portion AP, and the second transmission pad portion FBP disposed at the other end of the flexible circuit board 20 may be electrically connected to the PCB test pad section BP. The first transmission pad portion FAP may overlap the panel test pad portion AP, and the second transmission pad portion FBP may overlap the PCB test pad portion BP. An anisotropic conductive film ACF, as shown in FIG. 4, may electrically connect transmission pads of the first transmission pad portion FAP to panel pads of the panel test pad portion AP. Likewise, an anisotropic conductive film ACF may electrically connect transmission pads of the second transmission pad portion FBP to PCB pads of the PCB test pad portion BP.

The panel test pad portion AP may include a first panel pad group ALG and a second panel pad group ARG, each including a plurality of panel pads. The first panel pad group ALG and the second panel pad group ARG may be mirror symmetrical to each other with respect to the y-axis. In an embodiment, the first panel pad group ALG and the second panel pad group ARG may each include a first panel pad A1, a second panel pad A2, and a third panel pad A3. The first panel pad A1, the second panel pad A2, and the third panel pad A3 may be connected (e.g., electrically connected) to each other. The panel pads of the panel test pad portion AP may be test pads that may be used for measuring the connection resistance between the display panel 10 and the flexible circuit board 20.

The PCB test pad portion BP may include a first PCB pad group BLG and a second PCB pad group BRG, each including a plurality of PCB pads. The first PCB pad group BLG and the second PCB pad group BRG may be mirror symmetrical to each other with respect to the y-axis. In an embodiment, the first PCB pad group BLG and the second PCB pad group BRG may each include a first PCB pad B1, a second PCB pad B2, a third PCB pad B3, and a fourth PCB pad B4. The PCB pads of the PCB test pad portion BP may be test pads that may be used for measuring the connection resistance between the flexible circuit board 20 and the printed circuit board 30.

The test terminals TP may include a first test terminal group TPG1 and a second test terminal group TPG2. The first test terminal group TPG1 and the second test terminal group TPG2 may be mirror symmetrical to each other with respect to the y-axis. The first test terminal group TGP1 may be electrically connected to the first PCB pad group BLG, and the second test terminal group TGP2 may be electrically connected to the second PCB pad group BRG. The first test terminal group TGP1 and the second test terminal group TGP2 may each include a first input terminal IT, a second input terminal OT, a first measurement terminal MT1, a second measurement terminal MT2, and a third measurement terminal MT3. The first input terminal IT may be electrically connected to the first PCB pad B1. The second input terminal OT and the first measurement terminal MT1 may be electrically connected to the second PCB pad B2. The second measurement terminal MT2 may be electrically connected to the third PCB pad B3. The third measurement terminal MT3 may be electrically connected to the fourth PCB pad B4.

The first transmission pad portion FAP may include a 1st-1 transmission pad group FALG and a 1st-2 transmission pad group FARG, each including a plurality of transmission pads. The 1st-1 transmission pad group FALG and the 1st-2 transmission pad group FARG may be mirror symmetrical to each other with respect to the y-axis. The 1st-1 transmission pad group FALG and the 1st-2 transmission pad group FARG may each include a 1st-1 transmission pad FA1, a 1st-2 transmission pad FA2, and a 1st-3 transmission pad FA3. The 1st-1 transmission pad FA1 may overlap the first panel pad A1, the 1st-2 transmission pad FA2 may overlap the second panel pad A2, and the 1st-3 transmission pad FA3 may overlap the third panel pad A3. The transmission pads of the first transmission pad portion FAP may be test pads for measuring the connection resistance between the display panel 10 and the flexible circuit board 20.

The second transmission pad portion FBP may include a 2nd-1 transmission pad group FBLG and a 2nd-2 transmission pad group FBRG, each including a plurality of transmission pads. The 2nd-1 transmission pad group FBLG and the 2nd-2 transmission pad group FBRG may be mirror symmetrical to each other with respect to the y-axis. In an embodiment, the 2nd-1 transmission pad group FBLG and the 2nd-2 transmission pad group FBRG may each include a 2nd-1 transmission pad FB1, a 2nd-2 transmission pad FB2, and a 2nd-3 transmission pad FB3. The 2nd-1 transmission pad FB1 may overlap the first PCB pad B1, the 2nd-2 transmission pad FB2 may overlap the second PCB pad B2, and the 2nd-3 transmission pad FB3 may overlap the third PCB pad B3. The transmission pads of the second transmission pad portion FBP may be test pads for measuring the connection resistance between the flexible circuit board 20 and the printed circuit board 30.

The 2nd-1 transmission pad FB1 may be electrically connected to the 1st-1 transmission pad FA1 through a first wiring line FWL1 in the flexible circuit board 20. The 2nd-2 transmission pad FB2 may be electrically connected to the 1st-2 transmission pad FA2 by a second wiring line FWL21. The 2nd-3 transmission pad FB3 may be electrically connected to the 1st-2 transmission pad FA2 by a sub-wiring line FWL22, which may be connected to the second wiring line FWL21. In an embodiment, the 2nd-3 transmission pad FB3 may be electrically connected to the 1st-2 transmission pad FA2 through the sub-wiring line FWL22 and the second wiring line FWL21. A 2nd-4 transmission pad FB4 may be electrically connected to the 1st-3 transmission pad FA3 by a third wiring line FWL3. The first wiring line FWL1, the second wiring line FWL21, the sub-wiring line FWL22, and the third wiring line FWL3 may be disposed in or on the flexible circuit board 20. Each of the first wiring line FWL1, the second wiring line FWL21, the third wiring line FWL3, and the sub-wiring line FWL22 may include a conductive material having low resistance. For example, each of the first wiring line FWL1, the second wiring line FWL21, the third wiring line FWL3, and the sub-wiring line FWL22 may include a conductive material including copper (Cu).

The flexible circuit board 20 may electrically connect the first PCB pad B1 of the printed circuit board 30 to the first panel pad A1 of the display device 10. For example, the first PCB pad B1 may be electrically connected to the first panel pad A1 through the 2nd-1 transmission pad FB1 and the 1st-1 transmission pad FA1. The second PCB pad B2 may be electrically connected to the second panel pad A2. For example, the second PCB pad B2 may be electrically connected to the second panel pad A2 through the 2nd-2 transmission pad FB2 and the 1st-2 transmission pad FA2. The third PCB pad B3 may be electrically connected to the second panel pad A2. For example, the third PCB pad B3 may be electrically connected to the second panel pad A2 through the 2nd-3 transmission pad FB3 and the 1st-2 transmission pad FA2. The fourth PCB pad B4 may be electrically connected to the third panel pad A3. For example, the fourth PCB pad B4 may be electrically connected to the third panel pad A3 through the 2nd-4 transmission pad FB4 and the 1st-3 transmission pad FA3.

The display panel 10 may further include one or more first panel signal transmission pads SA and one or more second panel signal transmission pads SC. A plurality of first panel signal transmission pads SA and a plurality of second panel signal transmission pads SC may be provided. In an embodiment, the first panel signal transmission pad SA may be located between the first panel pad group ALG and the second panel pad group ARG. In an embodiment, the second panel signal transmission pad SC may overlap the integrated circuit chip 40. The display panel 10 may further include an IC input signal pad SD that overlaps the integrated circuit chip 40.

The integrated circuit chip 40 may further include a PCB input signal pad ISC electrically connected to the second panel signal transmission pad SC and an IC output signal pad ISD electrically connected to the IC input signal pad SD.

The flexible circuit board 20 may further include one or more first signal transmission pads FSA and one or more second signal transmission pads FSB. A plurality of first signal transmission pads FSA and a plurality of second signal transmission pads FSB may be provided. In an embodiment, the first signal transmission pad FSA may be located between the 1st-1 transmission pad group FALG and the 1st-2 transmission pad group FARG. In an embodiment, the second signal transmission pad FSB may be located between the 2nd-1 transmission pad group FBLG and the 2nd-2 transmission pad group FBRG.

The printed circuit board 30 may further include one or more PCB output signal pads SB. A plurality of PCB output signal pads SB may be provided. In an embodiment, the PCB output signal pad SB may be located between the first PCB pad group BLG and the second PCB pad group BRG.

The first signal transmission pad FSA, the second signal transmission pad FSB, the first panel signal transmission pad SA, and the second panel signal transmission pad SC may electrically connect the PCB output signal pad SB of the printed circuit board 30 to the PCB input signal pad ISC of the integrated circuit chip 40. Accordingly, signals from the printed circuit board 30 may be transmitted to the integrated circuit chip 40.

Signals output from the integrated circuit chip 40 may be transmitted to the data line DL of the display panel 10 and the like through the IC output signal pad ISD (see FIG. 2) of the integrated circuit chip 40 and the IC input signal pad SD (see FIG. 3) of the display panel 10.

FIG. 4 shows a perspective view illustrating structures in current paths used during connection resistance measurement according to the embodiment of FIGS. 2 and 3.

Referring to FIGS. 2 to 4, when a test current is applied to the first input terminal IT, the test current may flow along a current path from the first input terminal IT to the second input terminal OT. The second input terminal OT may be referred to as an output terminal. In an embodiment, when a test current is applied to the first input terminal IT, a current may flow through a current path including the first PCB pad B1, the first panel pad A1, the second panel pad A2, and the second PCB pad B2. In an embodiment, when a test current is applied to the first input terminal IT, a test current may flow through a current path including the first PCB pad B1, the 2nd-1 transmission pad FB1, the 1st-1 transmission pad FA1, the first panel pad A1, the second panel pad A2, the 1st-2 transmission pad FA2, the 2nd-2 transmission pad FB2, and the second PCB pad B2.

In an embodiment, a current source for measuring the connection resistance (hereinafter referred to as first connection resistance) between the panel test pad portion AP and the first transmission pad portion FAP and a current source for measuring the connection resistance (hereinafter referred to as second connection resistance) between the PCB test pad portion BP and the second transmission pad portion FBP may be connected to each other in a common current structure. In the present specification, the term “common current structure” may refer to a structure in which a plurality of current sources share a common current path. That is, a current source for measuring the first connection resistance between the display panel 10 and the flexible circuit board 20, and a current source for measuring the second connection resistance between the flexible circuit board 20 and the printed circuit board 30 may be connected to each other in a common current structure. The common current structure can be connected to apply current to the first input terminal IT and the second input terminal OT for simultaneous or independent measurements of the first connection resistance and the second connection resistance.

The second connection resistance, which is the connection resistance between the second transmission pad portion FBP of the flexible circuit board 20 and the PCB test pad portion BP of the printed circuit board 30, may be measured by electrically connecting a current source to allow current from the first input terminal IT to the second input terminal OT and connecting a voltmeter to measure the voltage of the first measurement terminal MT1 and the voltage of the second measurement terminal MT2. The voltage difference between first measurement terminal MT1 and the second measurement terminal MT2 may be used to derive the second connection resistance.

The first connection resistance, which is the connection resistance between the first transmission pad portion FAP of the flexible circuit board 20 and the panel test pad portion AP of the display panel 10, may be measured by electrically connecting a current source to allow current from the first input terminal IT to the second input terminal OT and connecting a voltmeter to measure the voltage of the second measurement terminal MT2 and the voltage of the third measurement terminal MT3. The voltage difference between the third measurement terminal MT3 and the second measurement terminal MT2 may be used to derive the first connection resistance.

In an embodiment, the first wiring line FWL1, the second wiring line FWL21, and the third wiring line FWL3 may be disposed on the flexible circuit board 20 and may each have a low resistance value. In an embodiment, in order to further reduce the resistance value of the second wiring line FWL21, the width of the second wiring line FWL21 may be made greater than the width of the first wiring line FWL1 or the width of the third wiring line FWL3. In an embodiment, the thicknesses of the first wiring line FWL1, the second wiring line FWL21, the third wiring line FWL3, and the sub-wiring line FWL22 may be substantially the same.

Each wiring line (e.g., the first to third wiring lines FWL1, FWL21, and FWL3) connecting the first transmission pad portion FAP to the second transmission pad portion FBP may have a low resistance value, causing the voltage difference between the first transmission pad portion FAP and the second transmission pad portion FBP to be small. As described above, the second measurement terminal MT2 connected to the third PCB pad B3 may be used for both the measurement of the first connection resistance and the measurement of the second connection resistance. For example, as the sub-wiring line FWL22 is connected between the second wiring line FWL21, which connects the 1st-2 transmission pad FA2 and the 2nd-2 transmission pad FB2 to each other, and the 1st-3 transmission pad FB3 and thus the third PCB pad B3 is electrically connected to the 1st-2 transmission pad FA2, the second measurement terminal MT2 may be used for both the measurement of the first connection resistance and the measurement of the second connection resistance

In an embodiment, as described above, a current source for measuring the first connection resistance between the panel test pad portion AP and the first transmission pad portion FAP and a current source for measuring the second connection resistance between the PCB test pad portion BP and the second transmission pad portion FBP may be connected to each other in a common current structure and the second measurement terminal MT2 may be used for both the measurement of the first connection resistance and the measurement of the second connection resistance, and thus, the number of test terminals TP and the number of transmission pads arranged in the second transmission pad portion FBP may be reduced.

In the case of the display apparatus 1 according to an embodiment described with reference to FIGS. 2 to 4, the number of test terminals TP used to measure both the first connection resistance between the panel test pad portion AP and the first transmission pad portion FAP and the second connection resistance between the PCB test pad portion BP and the second transmission pad portion FBP is five for each test pad group (e.g., the first test pad group TPG1 and the second test pad group TPG2). In addition, the number of transmission pads of the second transmission pad portion FBP required to measure the first connection resistance and the second connection resistance is four for each second transmission pad group (e.g., the 2nd-1 transmission pad group FBLG and the 2nd-2 transmission pad group FBRG).

In a comparative example that employs separate 4-terminal measurements, a total of four test terminals including two input terminals and two measurement terminals are required to measure the first connection resistance between the panel test pad portion AP and the first transmission pad portion FAP. Likewise, to measure the second connection resistance between the PCB test pad portion BP and the second transmission pad portion FBP, a total of four test terminals including two input terminals and two measurement terminals are required. Accordingly, the number of test terminals TP required to measure both the first connection resistance and the second connection resistance according to the comparative example is eight for each test pad group (e.g., the first test pad group TPG1 and the second test pad group TPG2).

However, in the display apparatus 1 according to the present embodiment, the number of test terminals TP required to measure both the first connection resistance and the second connection resistance may be reduced to 5 for each test pad group (e.g., the first test pad group TPG1 and the second test pad group TPG2). This reduces the space occupied by the test terminals TP on the printed circuit board 30, and as a result, restrictions on the design and arrangement of test pads may be dramatically reduced, and the printed circuit board 30 may be miniaturized.

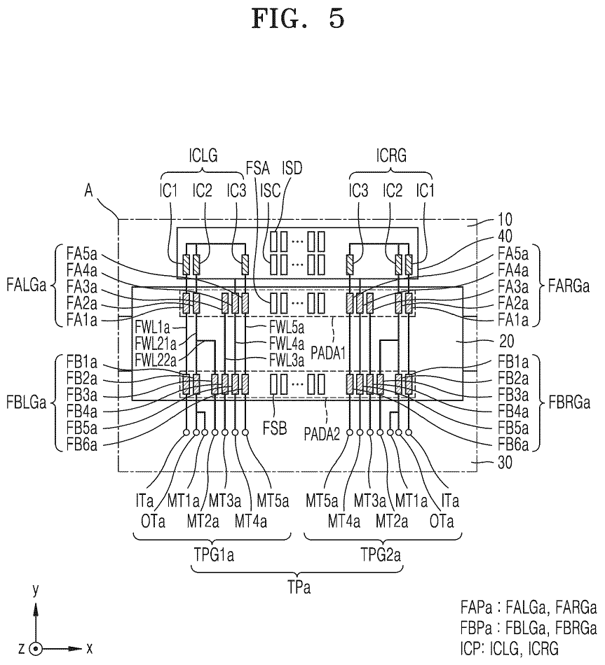

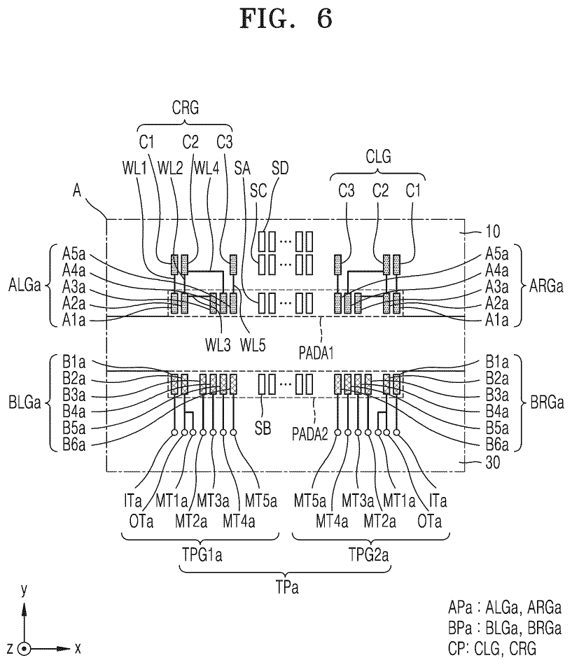

FIG. 5 is an enlarged view of the area ‘A’ of FIG. 1A according to an embodiment. FIG. 6 is an enlarged view of an embodiment of the area ‘A’ of FIG. 6 excluding the flexible circuit board 20 and the integrated circuit chip 40. The embodiments shown in FIGS. 5 and 6 contain some of the same components that are described above with reference to FIGS. 2 and 3 and identified by the same reference numerals used in FIGS. 2 and 3, and the description below may omit redundant description of such components to focus on how the components in FIGS. 5 and 6 may differ from the components described above.

Referring to FIGS. 5 and 6, the integrated circuit chip 40 may further include an IC test pad portion ICP. The display panel 10 may further include an IC transmission pad portion CP electrically connected to the IC test pad portion ICP of the integrated circuit chip 40. The IC transmission pad portion CP of the display panel 10 may overlap the IC test pad portion ICP of the integrated circuit chip 40. IC transmission pads of the IC transmission pad portion CP may respectively be electrically connected to IC test pads of the IC test pad portion ICP. The IC test pads of the IC test pad portion ICP and the IC transmission pads of the IC transmission pad portion CP may be test pads for measuring the connection resistance between the display panel 10 and the integrated circuit chip 40.

The IC test pad portion ICP may include a first IC test pad group ICLG and a second IC test pad group ICRG, each including a plurality of IC test pads. The first IC test pad group ICLG and the second IC test pad group ICRG may be mirror symmetrical to each other with respect to the y-axis. In an embodiment, the first IC test pad group ICLG and the second IC test pad group ICRG may each include a first IC test pad IC1, a second IC test pad IC2, and a third IC test pad IC3. The first IC test pad IC1, the second IC test pad IC2, and the third IC test pad IC3 may be connected (e.g., electrically connected) to each other.

In an embodiment, the PCB input signal pad ISC may be located between the first IC test pad group ICLG and the second IC test pad group ICRG. In an embodiment, the IC output signal pad ISD may be located between the first IC test pad group ICLG and the second IC test pad group ICRG.

The IC transmission pad portion CP may include a first IC transmission pad group CLG and a second IC transmission pad group CRG, each including a plurality of IC transmission pads. The first IC transmission pad group CLG and the second IC transmission pad group CRG may be mirror symmetrical to each other with respect to the y-axis. In an embodiment, the first IC transmission pad group CLG and the second IC transmission pad group CRG may each include a first IC transmission pad C1, a second IC transmission pad C2, and a third IC transmission pad C3. The first IC transmission pad C1 may overlap the first IC test pad IC1, the second IC transmission pad C2 may overlap the second IC test pad IC2, and the third IC transmission pad C3 may overlap the third IC test pad IC3.

A panel test pad portion APa on the display panel 10 may include a first panel pad group ALGa and a second panel pad group ARGa, each including a plurality of panel pads. The first panel pad group ALGa and the second panel pad group ARGa may be mirror symmetrical to each other with respect to the y-axis. In an embodiment, the first panel pad group ALGa and the second panel pad group ARGa may each include a first panel pad A1a, a second panel pad A2a, a third panel pad A3a, a fourth panel pad A4a, and a fifth panel pad A5a.

The first panel pad A1a may be electrically connected to the first IC transmission pad C1 by a first panel wiring line WL1. The second panel pad A2a may be electrically connected to the second IC transmission pad C2 by a second panel wiring line WL2. The third panel pad A3a may be electrically connected to the second panel pad A2a by a third panel wiring line WL3. In an embodiment, the third panel wiring line WL3 may connect the second panel pad A2a and the third panel pad A3a to each other. In an embodiment, the third panel pad A3a may be electrically connected to the second IC transmission pad C2 through the third panel wiring line WL3 and the second panel pad A2a. The fourth panel pad A4a may be electrically connected to the second IC transmission pad C2 by a fourth panel wiring line WL4. The fifth panel pad A5a may be electrically connected to the third IC transmission pad C3 by a fifth panel wiring line WL5. The first panel wiring line WL1, the second panel wiring line WL2, the third panel wiring line WL3, the fourth panel wiring line WL4, and the fifth panel wiring line WL5 may be disposed in or on the display panel 10.

A PCB test pad portion BPa may include a first PCB pad group BLGa and a second PCB pad group BRGa, each including a plurality of PCB pads that may be in or on the printed circuit board 30. The first PCB pad group BLGa and the second PCB pad group BRGa may be mirror symmetrical to each other with respect to the y-axis. In an embodiment, the first PCB pad group BLGa and the second PCB pad group BRGa may each include a first PCB pad B1a, a second PCB pad B2a, a third PCB pad B3a, a fourth PCB pad B4a, a fifth PCB pad B5a, and a sixth PCB pad B6a.

Test terminals TPa may include a first test terminal group TPG1a and a second test terminal group TPG2a that may be in or on the printed circuit board 30. The first test terminal group TPG1a and the second test terminal group TPG2a may be mirror symmetrical to each other with respect to the y-axis. The first test terminal group TGP1a may be electrically connected to the first PCB pad group BLGa, and the second test terminal group TGP2a may be electrically connected to the second PCB pad group BRGa.

The first test terminal group TGP1a and the second test terminal group TGP2a may each include a first input terminal ITa, a second input terminal OTa, a first measurement terminal MT1a, a second measurement terminal MT2a, a third measurement terminal MT3a, a fourth measurement terminal MT4a, and a fifth measurement terminal MT5a. The first input terminal ITa may be electrically connected to the first PCB pad B1a. The second input terminal OTa and the first measurement terminal MT1a may be electrically connected to the second PCB pad B2a. The second measurement terminal MT2a may be electrically connected to the third PCB pad B3a. The third measurement terminal MT3a may be electrically connected to the fourth PCB pad B4a. The fourth measurement terminal MT4a may be electrically connected to the fifth PCB pad B5a. The fifth measurement terminal MT5a may be electrically connected to the sixth PCB pad B6a.

A first transmission pad portion FAPa may include a 1st-1 transmission pad group FALGa and a 1st-2 transmission pad group FARGa, each including a plurality of transmission pads that may be in or on the flexible printed circuit board 20. The 1st-1 transmission pad group FALGa and the 1st-2 transmission pad group FARGa may be mirror symmetrical to each other with respect to the y-axis. The 1st-1 transmission pad group FALGa and the 1st-2 transmission pad group FARGa may each include a 1st-1 transmission pad FA1a, a 1st-2 transmission pad FA2a, a 1st-3 transmission pad FA3a, a 1st-4 transmission pad FA4a, and a 1st-5 transmission pad FA5a. The 1st-1 transmission pad FA1a may overlap the first panel pad A1a, the 1st-2 transmission pad FA2a may overlap the second panel pad A2a, and the 1st-3 transmission pad FA3a may overlap the third panel pad A3a. The 1st-4 transmission pad FA4a may overlap the fourth panel pad A4a, and the 1st-5 transmission pad FA5 may overlap the fifth panel pad A5.

A second transmission pad portion FBPa may include a 2nd-1 transmission pad group FBLGa and a 2nd-2 transmission pad group FBRGa, each including a plurality of transmission pads that may be in or on the flexible printed circuit board 20. The 2nd-1 transmission pad group FBLGa and the 2nd-2 transmission pad group FBRGa may be mirror symmetrical to each other with respect to the y-axis. In an embodiment, the 2nd-1 transmission pad group FBLGa and the 2nd-2 transmission pad group FBRGa may each include a 2nd-1 transmission pad FB1a, a 2nd-2 transmission pad FB2a, a 2nd-3 transmission pad FB3a, a 2nd-4 transmission pad FB4a, a 2nd-5 transmission pad FB5a, and a 2nd-6 transmission pad FB6a. The 2nd-1 transmission pad FB1a may overlap the first PCB pad B1a, the 2nd-2 transmission pad FB2a may overlap the second PCB pad B2a, and the 2nd-3 transmission pad FB3a may overlap the third PCB pad B3a. The 2nd-4 transmission pad FB4a may overlap the fourth PCB pad B4a, the 2nd-5 transmission pad FB5a may overlap the fifth PCB pad B5a, and the 2nd-6 transmission pad FB6a may overlap the sixth PCB pad B6a.

The 2nd-1 transmission pad FB1a may be electrically connected to the 1st-1 transmission pad FA1a through a first wiring line FWL1a. The 2nd-2 transmission pad FB2a may be electrically connected to the 1st-2 transmission pad FA2a through a second wiring line FWL21a. The 2nd-3 transmission pad FB3a may be electrically connected to the 1st-2 transmission pad FA2a through a sub-wiring line FWL22a, which may be connected to the second wiring line FWL21a. In an embodiment, the 2nd-3 transmission pad FB3a may be electrically connected to the 1st-2 transmission pad FA2a through the sub-wiring line FWL22a and the second wiring line FWL21a. The 2nd-4 transmission pad FB4a may be electrically connected to the 1st-3 transmission pad FA3a by a third wiring line FWL3a. The 2nd-5 transmission pad FB5a may be electrically connected to the 1st-4 transmission pad FA4a by a fourth wiring line FWL4a. The 2nd-6 transmission pad FB6a may be electrically connected to the 1st-5 transmission pad FA5a by a fifth wiring line FWL5a. The first wiring line FWL1a, the second wiring line FWL21a, the sub-wiring line FWL22a, the third wiring line FWL3a, the fourth wiring line FWL4a, and the fifth wiring line FWL5a may be in or on the flexible circuit board 20.

The first wiring line FWL1a, the second wiring line FWL21a, the third wiring line FWL3a, the fourth wiring line FWL4a, the fifth wiring line FWL5a, and the sub-wiring line FWL22a may each include a conductive material having low resistance. For example, the first wiring line FWL1a, the second wiring line FWL21a, the third wiring line FWL3a, the fourth wiring line FWL4a, the fifth wiring line FWL5a, and the sub-wiring line FWL22a may each include a conductive material including copper (Cu). In an embodiment, the resistance of each of the first wiring line FWL1a, the second wiring line FWL21a, the third wiring line FWL3a, the fourth wiring line FWL4a, the fifth wiring line FWL5a, and the sub-wiring line FWL22a may be less than the resistance of each of the first panel wiring line WL1, the second panel wiring line WL2, the third panel wiring line WL3, the fourth panel wiring line WL4, and the fifth panel wiring line WL5.

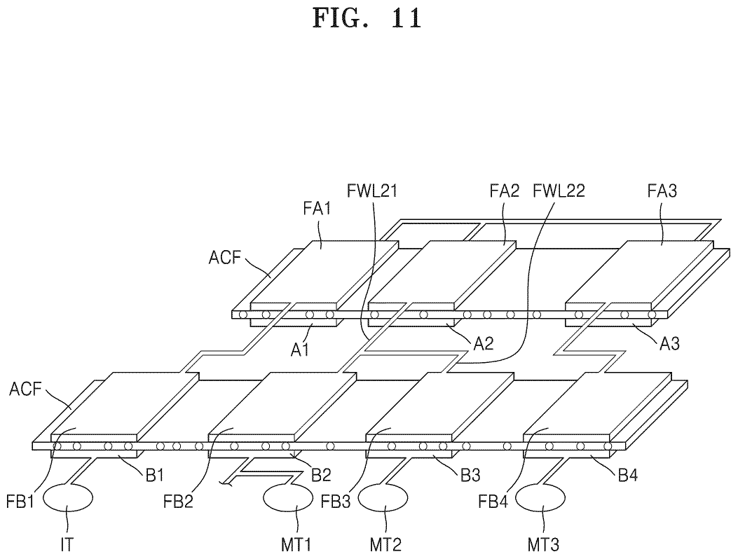

An anisotropic conductive film ACF, as shown in FIG. 11, may electrically connect the transmission pads of the first transmission pad portion FAPa respectively to the panel pads of the panel test pad portion APa. The anisotropic conductive film ACF may also electrically connect the transmission pads of the second transmission pad portion FBPa respectively to the PCB pads of the PCB test pad portion BPa. The anisotropic conductive film ACF may also electrically connect the transmission pads of the IC transmission pad portion CP respectively to the IC test pads of the IC test pad portion ICP.

The first PCB pad B1a may be electrically connected to the first panel pad A1a. For example, the first PCB pad B1a may be electrically connected to the first panel pad A1a through the 2nd-1 transmission pad FB1a and the 1st-1 transmission pad FA1a. The second PCB pad B2a may be electrically connected to the second panel pad A2a. For example, the second PCB pad B2a may be electrically connected to the second panel pad A2a through the 2nd-2 transmission pad FB2a and the 1st-2 transmission pad FA2a. The third PCB pad B3a may be electrically connected to the second panel pad A2a. For example, the third PCB pad B3a may be electrically connected to the second panel pad A2a through the 2nd-3 transmission pad FB3a and the 1st-2 transmission pad FA2a. The fourth PCB pad B4a may be electrically connected to the third panel pad A3a. For example, the fourth PCB pad B4a may be electrically connected to the third panel pad A3a through the 2nd-4 transmission pad FB4a and the 1st-3 transmission pad FA3a. The fifth PCB pad B5a may be electrically connected to the fourth panel pad A4a. For example, the fifth PCB pad B5a may be electrically connected to the fourth panel pad A4a through the 2nd-5 transmission pad FB5a and the 1st-4 transmission pad FA4a. The sixth PCB pad B6a may be electrically connected to the fifth panel pad A5a. For example, the sixth PCB pad B6a may be electrically connected to the fifth panel pad A5a through the 2nd-6 transmission pad FB6a and the 1st-5 transmission pad FA5a.

The first panel pad A1a may be electrically connected to the first IC test pad IC1. For example, the first panel pad A1a may be electrically connected to the first IC test pad IC1 through the first IC transmission pad C1. The second panel pad A2a may be electrically connected to the second IC test pad IC2. For example, the second panel pad A2a may be electrically connected to the second IC test pad IC2 through the second IC transmission pad C2. The third panel pad A3a may be electrically connected to the second IC test pad IC2. For example, the third panel pad A3a may be electrically connected to the second IC test pad IC2 through the second panel pad A2a and the second IC transmission pad C2. The fourth panel pad A4a may be electrically connected to the second IC test pad IC2. For example, the fourth panel pad A4a may be electrically connected to the second IC test pad IC2 through the second IC transmission pad C2. The fifth panel pad A5a may be electrically connected to the third IC test pad IC3. For example, the fifth panel pad A5a may be electrically connected to the third IC test pad IC3 through the third IC transmission pad C3.

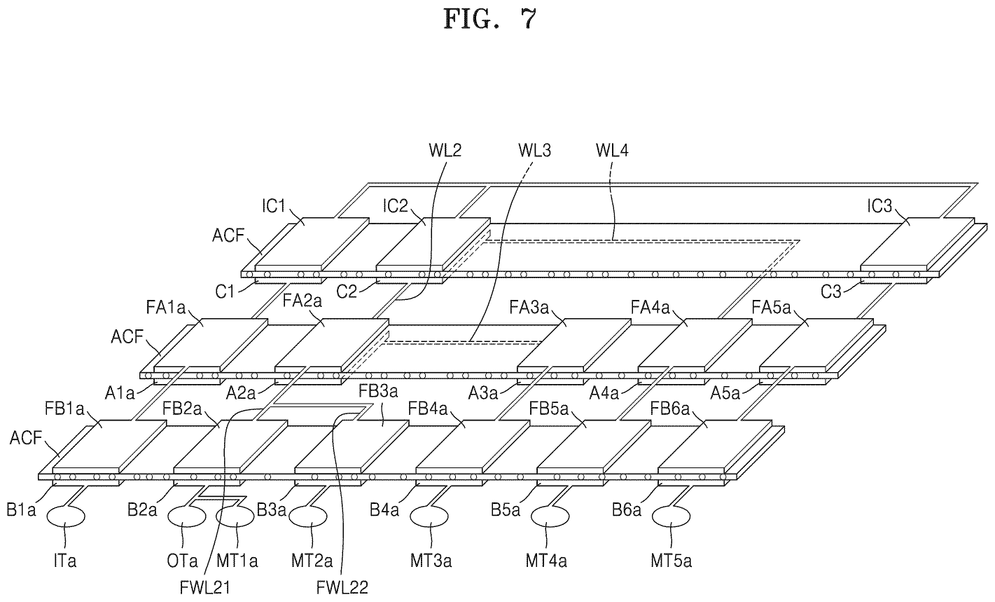

FIG. 7 shows a perspective view conceptually illustrating structures in current paths used during connection resistance measurement according to the embodiment of FIGS. 5 and 6.

Referring to FIGS. 5 to 7, when a test current may be applied to the first input terminal ITa, a current path is formed between the first input terminal ITa and the second input terminal Ota. In an embodiment, when a test current is applied to the first input terminal ITa, the test current may flow through a current path including the first PCB pad B1a, the first panel pad A1a, the first IC test pad IC1, the second IC test pad IC2, the second panel pad A2a, and the second PCB pad B2a. In an embodiment, when a test current is applied to the first input terminal ITa, the test current may flow through a current path that includes the first PCB pad Ba, the 2nd-1 transmission pad FB1a, the 1st-1 transmission pad FA1a, the first panel pad A1a, the first IC transmission pad C1, the first IC test pad IC1, the second IC test pad IC2, the second IC transmission pad C2, the second panel pad A2a, the 1st-2 transmission pad FA2a, the 2nd-2 transmission pad FB2a, and the second PCB pad B2a.

In an embodiment, a current source for measuring the connection resistance (hereinafter referred to as third connection resistance) between the IC transmission pad portion CP and the IC test pad portion ICP, a current source for measuring the connection resistance (e.g., first connection resistance) between the panel test pad portion APa and the first transmission pad portion FAPa, and a current source for measuring the connection resistance (e.g., second connection resistance) between the PCB test pad portion BPa and the second transmission pad portion FBPa may be connected to each other in a common current structure. That is, a current source for measuring the third connection resistance between the display panel 10 and the integrated circuit chip 40, a current source for measuring the first connection resistance between the display panel 10 and the flexible circuit board 20, and a current source for measuring the second connection resistance between the flexible circuit board 20 and the printed circuit board 30 may be connected to each other in a common current structure.

The second connection resistance, which is the resistance between the second transmission pad portion FBPa of the flexible circuit board 20 and the PCB test pad portion BPa of the printed circuit board 30, may be measured by electrically connecting a current source to allow current from the first input terminal ITa to the second input terminal OTa and connecting a voltmeter to each of the first measurement terminal MT1a and the second measurement terminal MT2a to measure the voltage of the first measurement terminal MT1a and the voltage of the second measurement terminal MT2a.

The first connection resistance, which is the resistance between the first transmission pad portion FAPa of the flexible circuit board 20 and the panel test pad portion APa of the display panel 10, may be measured by electrically connecting a current source to allow current from the first input terminal ITa to the second input terminal OTa and connecting a voltmeter to each of the second measurement terminal MT2a and the third measurement terminal MT3a to measure the voltage of the second measurement terminal MT2a and the voltage of the third measurement terminal MT3a.

The third connection resistance, which is the resistance between the IC test pad portion ICP of the integrated circuit chip 40 and the IC transmission pad portion CP of the display panel 10, may be measured by electrically connecting a current source to the first input terminal ITa and the second input terminal OTa to apply a current and connecting a voltmeter to each of the fourth measurement terminal MT4a and the fifth measurement terminal MT5a to measure the voltage of the fourth measurement terminal MT4a and the voltage of the fifth measurement terminal MT5a,.

In an embodiment, similar to that described with reference to FIGS. 2 to 4, because a wiring line (e.g., the first to fifth wiring lines FWL1a, FWL21a, FWL3a, FWL4a, and FWL5a) connecting the first transmission pad portion FAPa to the second transmission pad portion FBPa has a low resistance value, the voltage difference between the first transmission pad portion FAPa and the second transmission pad portion FBPa may be small. Accordingly, the second measurement terminal MT2a connected to the third PCB pad B3a may be used for both the measurement of the first connection resistance and the measurement of the second connection resistance. For example, as the sub-wiring line FWL22a is connected between the second wiring line FWL21a, which connects the 1st-2 transmission pad FA2a and the 2nd-2 transmission pad FB2a to each other, and the 1st-3 transmission pad FB3a and thus the third PCB pad B3a is electrically connected to the 1st-2 transmission pad FA2a, the second measurement terminal MT2a may be used for both the measurement of the first resistance and the measurement of second connection resistance.

The first to fifth panel wiring lines WL1, WL2, WL3, WL4, and WL5 disposed on the display panel 10 may have resistance values that are greater than those of the first to fifth wiring lines FWL1a, FWL21a, FWL3a, FWL4a, and FWL5a disposed on the flexible circuit board 20. Accordingly, the third connection resistance between the IC transmission pad portion CP of the display panel 10 and the IC test pad portion ICP of the integrated circuit chip 40 may be measured using another measurement terminal (e.g., the fourth measurement terminal MT4a and the fifth measurement terminal MT5a) separate from a measurement terminal (e.g., the first measurement terminal MT1a and the second measurement terminal MT2a) used to measure the second connection resistance and a measurement terminal (e.g., the second measurement terminal MT2a and the third measurement terminal MT3a) used to measure the first connection resistance.

Accordingly, in the case of the display apparatus 1 according to an embodiment described with reference to FIGS. 5 to 7, the number of test terminals TPa used to measure all of the first connection resistance between the panel test pad portion APa and the first transmission pad portion FAPa, the second connection resistance between the PCB test pad portion BPa and the second transmission pad portion FBPa, and the third connection resistance between the IC transmission pad portion CP and the IC test pad portion ICP is five for each test pad group (e.g., the first test pad group TPG1a and the second test pad group TPG2a). In addition, the number of transmission pads of the second transmission pad portion FBPa used to measure the first to third connection resistances is 6 for each second transmission pad group (e.g., the 2nd-1 transmission pad group FBLGa and the 2nd-2 transmission pad group FALGa).

As described above, the number of test terminals required to measure the first connection resistance and the second connection resistance using a typical 4-terminal measurement method is eight for each test pad group. Furthermore, in the case of the typical 4-terminal measurement method, a total of four test terminals including two input terminals and two measurement terminals are required to measure the third connection resistance between the display panel 10 and the integrated circuit chip 40. That is, the number of test terminals required to measure all of the first to third connection resistances using the typical 4-terminal measurement method is eight for each test pad group (e.g., the first test pad group TPG1a and the second test pad group TPG2a).

In the display apparatus 1 according to the present embodiment, the number of test terminals TPa required to measure all of the first connection resistance, the second connection resistance, and the third connection resistance may be reduced to seven for each test pad group (e.g., the first test pad group TPG1a and the second test pad group TPG2a).

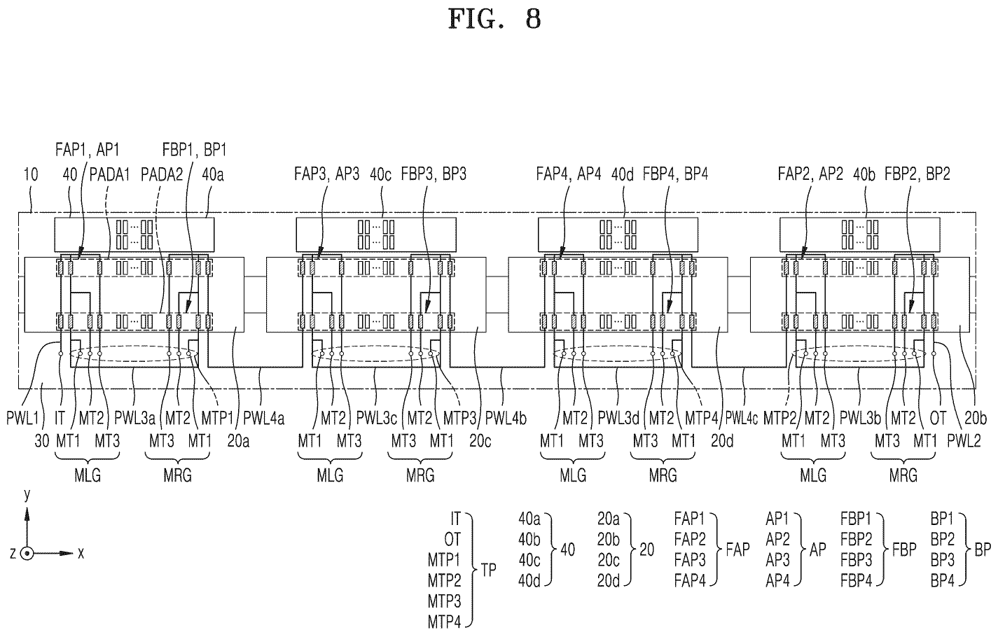

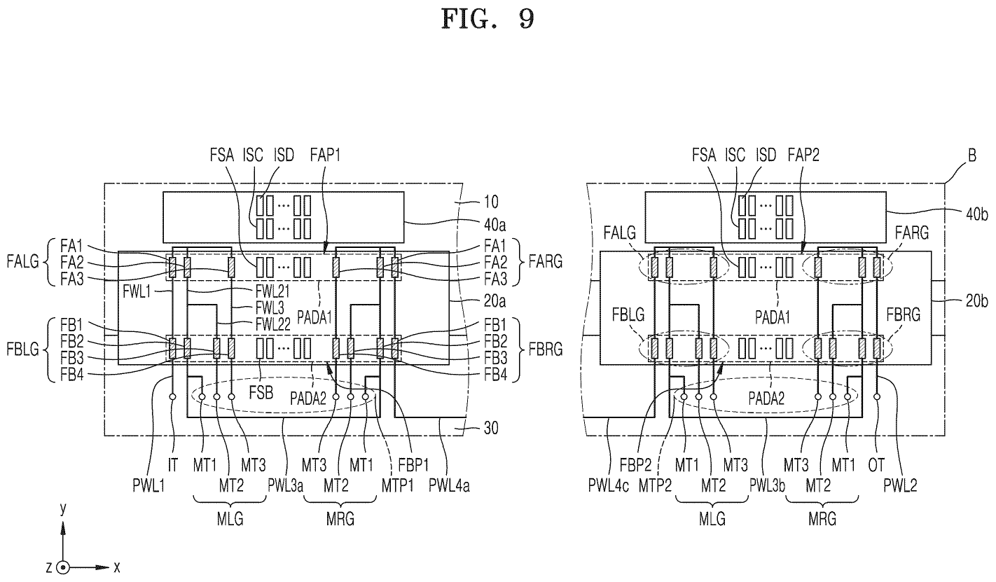

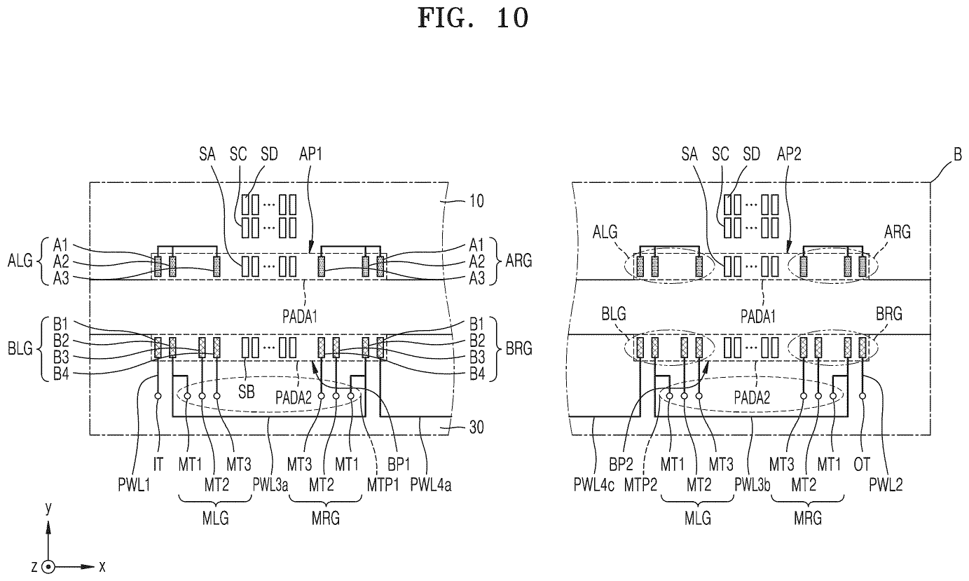

FIG. 8 is an enlarged view of an area ‘B’ of FIG. 1B according to an embodiment. FIG. 9 is an enlarged view of an embodiment of an area corresponding to the first flexible circuit board 20a and the second flexible circuit board 20b in FIG. 8. FIG. 10 is an enlarged view of FIG. 9 excluding the first and second flexible circuit boards 20a and 20b and the first and second integrated circuit chips 40a and 40b.

The embodiments shown in FIGS. 8 to 10 contain some of the same components that are described above with reference to FIGS. 2 and 3 and identified by the same or similar reference numerals used in FIGS. 2 and 3, and thus, the description below may omit redundant description of such components to focus on how the components in FIGS. 8 to 10 may differ from the components described above.

Referring to FIGS. 8 to 10, the display panel 10 may include a plurality of panel test pad portions AP. For example, the display panel 10 may include a first panel test pad portion AP1, a second panel test pad portion AP2, a third panel test pad portion AP3, and a fourth panel test pad portion AP4. Although FIG. 8 shows four panel test pad portions AP, the disclosure is not limited thereto. For example, three or more panel test pad portions AP may be provided. In an embodiment, the structures of the panel test pad portions AP may be substantially the same as each other.

In an embodiment, the third panel test pad portion AP3 and the fourth panel test pad portion AP4 may be arranged between the first panel test pad portion AP1 and the second panel test pad portion AP2. For example, the third panel test pad portion AP3 may be adjacent to the first panel test pad portion AP1. For example, the third panel test pad portion AP3 may be between the first panel test pad portion AP1 and the fourth panel test pad portion AP4. For example, the fourth panel test pad portion AP4 may be adjacent to the second panel test pad portion AP2. For example, the fourth panel test pad portion AP4 may be between the second panel test pad portion AP2 and the third panel test pad portion AP3.

Each of the first to fourth panel test pad portions AP1, AP2, AP3, and AP4 may include a first panel pad group ALG and a second panel pad group ARG. In an embodiment, the first panel pad group ALG and the second panel pad group ARG may each include a first panel pad A1, a second panel pad A2, and a third panel pad A3. The first panel pad A1, the second panel pad A2, and the third panel pad A3 may be connected (e.g., electrically connected) to each other.

The printed circuit board 30 may include a plurality of PCB test pad portions BP and test terminals TP. For example, the printed circuit board 30 may include a first PCB test pad portion BP1, a second PCB test pad portion BP2, a third PCB test pad portion BP3, and a fourth PCB test pad portion BP4. Although FIG. 8 shows four PCB test pad portions BP, the disclosure is not limited thereto. For example, three or more PCB test pad portions BP may be provided. In an embodiment, the structures of the PCB test pad portions BP may be substantially the same as each other.

Each of the first to fourth PCB test pad portions BP1, BP2, BP3, and BP4 may include a first PCB pad group BLG and a second PCB pad group BRG. In an embodiment, the first PCB pad group BLG and the second PCB pad group BRG may each include a first PCB pad B1, a second PCB pad B2, a third PCB pad B3, and a fourth PCB pad B4.

In an embodiment, the third PCB test pad portion BP3 and the fourth PCB test pad portion BP4 may be arranged between the first PCB test pad portion BP1 and the second PCB test pad portion BP2. For example, the third PCB test pad portion BP3 may be adjacent to the first PCB test pad portion BP1. For example, the third PCB test pad portion BP3 may be between the first panel test pad portion AP1 and the fourth PCB test pad portion BP4. For example, the fourth PCB test pad portion BP4 may be adjacent to the second PCB test pad portion BP2. For example, the fourth PCB test pad portion BP4 may be between the second PCB test pad portion BP2 and the third PCB test pad portion BP3.

The test terminals TP may include a plurality of measurement terminal portions each electrically connected to the first input terminal IT, the second input terminal OT, and the plurality of PCB test pad portions BP. For example, the test terminals TP may include a first measurement terminal portion MTP1 electrically connected to the first PCB test pad portion BP1, a second measurement terminal portion MTP2 electrically connected to the second PCB test pad portion BP2, a third measurement terminal portion MTP3 electrically connected to the third PCB test pad portion BP3, and a fourth measurement terminal portion MTP4 electrically connected to the fourth PCB test pad portion BP4.

The first input terminal IT may be electrically connected to the first PCB pad B1 of the first PCB pad group BLG of the first PCB test pad portion BP1. In an embodiment, the first input terminal IT may be electrically connected to the first PCB pad B1 of the first PCB pad group BLG of the first PCB test pad portion BP1 by a first PCB wiring line PWL1.

The second input terminal OT may be electrically connected to the first PCB pad B1 of the second PCB pad group BRG of the second PCB test pad portion BP2. In an embodiment, the second input terminal OT may be electrically connected to the first PCB pad B1 of the first PCB pad group BLG of the first PCB test pad portion BP1 by a second PCB wiring line PWL2.

Each of the first to fourth measurement terminal portions MTP1, MTP2, MTP3, and MTP4 may include a first measurement terminal group MLG and a second measurement terminal group MRG. The first measurement terminal group MLG and the second measurement terminal group MRG may be mirror symmetrical to each other with respect to a vertical axis (e.g., the y-axis) between the first measurement terminal group MLG and the second measurement terminal group MRG.

The first measurement terminal group MLG of each of the first to fourth measurement terminal portions MTP1, MTP2, MTP3, and MTP4 may be electrically connected to the first PCB pad group BLG of a corresponding PCB test pad portion BP. For example, the first measurement terminal group MLG of the first measurement terminal portion MTP1 may be electrically connected to the first PCB pad group BLG of the first PCB test pad portion BP1, the first measurement terminal group MLG of the second measurement terminal portion MTP2 may be electrically connected to the first PCB pad group BLG of the second PCB test pad portion BP2, the first measurement terminal group MLG of the third measurement terminal portion MTP3 may be electrically connected to the first PCB pad group BLG of the third PCB test pad portion BP3, and the first measurement terminal group MLG of the fourth measurement terminal portion MTP4 may be electrically connected to the first PCB pad group BLG of the fourth PCB test pad portion BP4.

The second measurement terminal group MRG of each of the first to fourth measurement terminal portions MTP1, MTP2, MTP3, and MTP4 may be electrically connected to the second PCB pad group BRG of a corresponding PCB test pad portion BP. For example, the second measurement terminal group MRG of the first measurement terminal portion MTP1 may be electrically connected to the second PCB pad group BRG of the first PCB test pad portion BP1, the second measurement terminal group MRG of the second measurement terminal portion MTP2 may be electrically connected to the second PCB pad group BRG of the second PCB test pad portion BP2, the second measurement terminal group MRG of the third measurement terminal portion MTP3 may be electrically connected to the second PCB pad group BRG of the third PCB test pad portion BP3, and the second measurement terminal group MRG of the fourth measurement terminal portion MTP4 may be electrically connected to the second PCB pad group BRG of the fourth PCB test pad portion BP4.

Each of the first measurement terminal group MLG and the second measurement terminal group MRG may include a first measurement terminal MT1, a second measurement terminal MT2, and a third measurement terminal MT3. The first measurement terminal group MLG may include a first measurement terminal MT1 electrically connected to the second PCB pad B2 of the first PCB pad group BLG, a second measurement terminal MT2 electrically connected to the third PCB pad B3 of the first PCB pad group BLG, and a third measurement terminal MT3 electrically connected to the fourth PCB pad B4 of the first PCB pad group BLG. The second measurement terminal group MRG may include a first measurement terminal MT1 electrically connected to the second PCB pad B2 of the second PCB pad group BRG, a second measurement terminal MT2 electrically connected to the third PCB pad B3 of the second PCB pad group BRG, and a third measurement terminal MT3 electrically connected to the fourth PCB pad B4 of the second PCB pad group BRG.

In an embodiment, a plurality of flexible circuit boards 20 may be provided. Each of the plurality of flexible circuit boards 20 may correspond to one panel test pad portion AP among the plurality of panel test pad portions AP and correspond to one PCB test pad portion BP among the plurality of PCB test pad portions BP. For example, the flexible circuit board 20 may include a first flexible circuit board 20a, a second flexible circuit board 20b, a third flexible circuit board 20c, and a fourth flexible circuit board 20d. In an embodiment, the structures of the flexible circuit boards 20 may be the same as each other.

One end of the first flexible circuit board 20a may be connected to the first panel test pad portion AP1, and the other end may be connected to the first PCB test pad portion BP1. One end of the second flexible circuit board 20b may be connected to the second panel test pad portion AP2, and the other end may be connected to the second PCB test pad portion BP2. One end of the third flexible circuit board 20c may be connected to the third panel test pad portion AP3, and the other end may be connected to the third PCB test pad portion BP3. One end of the fourth flexible circuit board 20d may be connected to the fourth panel test pad portion AP4, and the other end may be connected to the fourth PCB test pad portion BP4. Although FIG. 8 shows four flexible circuit boards 20, the disclosure is not limited thereto. For example, three or more flexible circuit boards 20 may be provided.

Each of the plurality of flexible circuit boards 20 may include a first transmission pad portion FAP disposed at one end thereof and a second transmission pad portion FBP disposed at an opposite end thereof. That is, the first to fourth flexible circuit boards 20a, 20b, 20c, and 20d may respectively include first transmission pad portions FAP1, FAP2, FAP3, and FAP4 disposed at ends thereof and second transmission pad portions FBP1, FBP2, FBP3, and FBP4 disposed at opposite ends of the first to fourth flexible circuit boards 20a, 20b, 20c, and 20d.

Each of the first transmission pad portions FAP1, FAP2, FAP3, and FAP4 may include a 1st-1 transmission pad group FALG and a 1st-2 transmission pad group FARG. The 1st-1 transmission pad group FALG and the 1st-2 transmission pad group FARG may each include a 1st-1 transmission pad FA1, a 1st-2 transmission pad FA2, and a 1st--3 transmission pad FA3.

Each of the second transmission pad portions FBP1, FBP2, FBP3, and FBP4 may include a 2nd-1 transmission pad group FBLG and a 2nd-2 transmission pad group FBRG. In an embodiment, the 2nd-1 transmission pad group FBLG and the 2nd-2 transmission pad group FBRG may each include a 2nd-1 transmission pad FB1, a 2nd-2 transmission pad FB2, and a 2nd-3 transmission pad FB3.

The first transmission pad portions FAP of the plurality of flexible circuit boards 20 may respectively be electrically connected to the panel test pad portions AP of a corresponding display panel 10. For example, the first transmission pad portion FAP1 of the first flexible circuit board 20a may be electrically connected to the first panel test pad portion AP1. For example, the first transmission pad portion FAP2 of the second flexible circuit board 20b may be electrically connected to the second panel test pad portion AP2. For example, the first transmission pad portion FAP3 of the third flexible circuit board 20c may be electrically connected to the third panel test pad portion AP3. For example, the first transmission pad portion FAP4 of the fourth flexible circuit board 20d may be electrically connected to the fourth panel test pad portion AP4.

The second transmission pad portions FBP of the first to fourth flexible circuit boards 20a, 20b, 20c, and 20d may respectively be electrically connected to the PCB test pad portions BP of the printed circuit board 30. For example, the second transmission pad portion FBP1 of the first flexible circuit board 20a may be electrically connected to the first PCB test pad portion BP1. For example, the second transmission pad portion FBP2 of the second flexible circuit board 20b may be electrically connected to the second PCB test pad portion BP2. For example, the second transmission pad portion FBP3 of the third flexible circuit board 20c may be electrically connected to the third PCB test pad portion BP3. For example, the second transmission pad portion FBP4 of the fourth flexible circuit board 20d may be electrically connected to the fourth PCB test pad portion BP4.

Each of the first to fourth flexible circuit boards 20a, 20b, 20c, and 20d may include a first wiring line FWL1, a second wiring line FWL21, a third wiring line FWL3, and a sub-wiring line FWL22. For convenience of description, the description below will focus on the first flexible circuit board 20a with reference to FIG. 9 since the first to fourth flexible circuit boards 20a, 20b, 20c, and 20d include the same configuration and the connection relationships of the first to fourth flexible circuit boards 20a, 20b, 20c, and 20d are substantially the same.

The 2nd-1 transmission pad FB1 may be electrically connected to the 1st-1 transmission pad FA1 through the first wiring line FWL1. The 2nd-2 transmission pad FB2 may be electrically connected to the 1st-2 transmission pad FA2 by the second wiring line FWL21. The 2nd-3 transmission pad FB3 may be electrically connected to the 1st-2 transmission pad FA2 by the sub-wiring line FWL22 connected to the second wiring line FWL21. In an embodiment, the 2nd-3 transmission pad FB3 may be electrically connected to the 1st-2 transmission pad FA2 through the sub-wiring line FWL22 and the second wiring line FWL21. The 2nd-4 transmission pad FB4 may be electrically connected to the 1st-3 transmission pad FA3 by the third wiring line FWL3. The first wiring line FWL1, the second wiring line FWL21, the sub-wiring line FWL22, and the third wiring line FWL3 may be disposed on the first flexible circuit board 20a. Each of the first wiring line FWL1, the second wiring line FWL21, the third wiring line FWL3, and the sub-wiring line FWL22 may include a conductive material having low resistance. For example, each of the first wiring line FWL1, the second wiring line FWL21, the third wiring line FWL3, and the sub-wiring line FWL22 may include a conductive material including Cu.

Transmission pads of the first transmission pad portion FAP may be electrically connected to panel pads of the panel test pad portion AP by an anisotropic conductive film ACF, as shown in FIG. 11. Likewise, transmission pads of the second transmission pad portion FBP may be electrically connected to PCB pads of the PCB test pad portion BP by an anisotropic conductive film ACF.

In an embodiment, the electrical connection relationship between pads of the panel test pad portion AP, the first transmission pad portion FAP, the second transmission pad portion FBP, and the PCB test pad portion BP, which correspond to each other, may be the same as that in the embodiment described with reference to FIGS. 2 and 3.

The first transmission pad portions FAP1, FAP2, FAP3, and FAP4 of the first to fourth flexible circuit boards 20a, 20b, 20c, and 20d may respectively overlap the panel test pad portions AP of a corresponding display panel 10. For example, the first transmission pad portion FAP1 of the first flexible circuit board 20a may overlap the first panel test pad portion AP1. For example, the first transmission pad portion FAP2 of the second flexible circuit board 20b may overlap the second panel test pad portion AP2. For example, the first transmission pad portion FAP3 of the third flexible circuit board 20c may overlap the third panel test pad portion AP3. For example, the first transmission pad portion FAP4 of the fourth flexible circuit board 20d may overlap the fourth panel test pad portion AP4.

The second transmission pad portions FBP1, FBP2, FBP3, and FBP4 of the first to fourth flexible circuit boards 20a, 20b, 20c, and 20d may respectively overlap the PCB test pad portions BP. For example, the second transmission pad portion FBP1 of the first flexible circuit board 20a may overlap the first PCB test pad portion BP1. For example, the second transmission pad portion FBP2 of the second flexible circuit board 20b may overlap the second PCB test pad portion BP2. For example, the second transmission pad portion FBP3 of the third flexible circuit board 20c may overlap the third PCB test pad portion BP3. For example, the second transmission pad portion FBP4 of the fourth flexible circuit board 20d may overlap the fourth PCB test pad portion BP4.

In an embodiment, the third flexible circuit board 20c and the fourth flexible circuit board 20d may be arranged between the first flexible circuit board 20a and the second flexible circuit board 20b. For example, the third flexible circuit board 20c may be adjacent to the first flexible circuit board 20a. For example, the third flexible circuit board 20c may be between the first flexible circuit board 20a and the fourth flexible circuit board 20d. For example, the fourth flexible circuit board 20d may be adjacent to the second flexible circuit board 20b. For example, the fourth flexible circuit board 20d may be between the second flexible circuit board 20b and the third flexible circuit board 20c.

In an embodiment, the display apparatus 1 may include a plurality of integrated circuit chips 40. For example, the display apparatus 1 may include a first integrated circuit chip 40a, a second integrated circuit chip 40b, a third integrated circuit chip 40c, and a fourth integrated circuit chip 40d. Although FIG. 8 shows four integrated circuit chips 40, the disclosure is not limited thereto. In an embodiment, the integrated circuit chips 40 may be at respective positions corresponding to the flexible circuit boards 20. In an embodiment, each of integrated circuit chips 40 may have a structure that is substantially the same as the structure of each of the other integrated circuit chips 40.

In each of the PCB test pad portions BP, the second PCB pad B2 of the first PCB pad group BLG may be electrically connected to the second PCB pad B2 of the second PCB pad group BRG of the first PCB test pad portion BP1. For example, the second PCB pad B2 of the first PCB pad group BLG of the first PCB test pad portion BP1 may be electrically connected to the second PCB pad B2 of the second PCB pad group BRG of the first PCB test pad portion BP1. In an embodiment, the second PCB pad B2 of the first PCB pad group BLG of the first PCB test pad portion BP1 may be electrically connected to the second PCB pad B2 of the second PCB pad group BRG of the first PCB test pad portion BP1 by a 3rd-1 PCB wiring line PWL3a. Likewise, the second PCB pad B2 of the first PCB pad group BLG of the second PCB test pad portion BP2 may be electrically connected to the second PCB pad B2 of the second PCB pad group BRG of the second PCB test pad portion BP2 by a 3rd-2 PCB wiring line PWL3b. Likewise, the second PCB pad B2 of the first PCB pad group BLG of the third PCB test pad portion BP3 may be electrically connected to the second PCB pad B2 of the second PCB pad group BRG of the third PCB test pad portion BP3 by a 3rd-3 PCB wiring line PWL3c. Likewise, the second PCB pad B2 of the first PCB pad group BLG of the fourth PCB test pad portion BP4 may be electrically connected to the second PCB pad B2 of the second PCB pad group BRG of the fourth PCB test pad portion BP4 by a 3rd-4 PCB wiring line PWL3d.

The first PCB pad B1 of the second PCB pad group BRG of any one of the PCB test pad portions BP may be electrically connected to the first PCB pad B1 of the first PCB pad group BLG of another PCB test pad portion BP adjacent to the one of the PCB test pad portions BP. For example, the first PCB pad B1 of the second PCB pad group BRG of the first PCB test pad portion BP1 may be electrically connected to the first PCB pad B1 of the first PCB pad group BLG of the third PCB test pad portion BP3 by a 4th-1 PCB wiring line PWL4a. Likewise, the first PCB pad B1 of the second PCB pad group BRG of the third PCB test pad portion BP3 may be electrically connected to the first PCB pad B1 of the first PCB pad group BLG of the fourth PCB test pad portion BP4 by a 4th-2 PCB wiring line PWL4b. Likewise, the first PCB pad B1 of the second PCB pad group BRG of the fourth PCB test pad portion BP4 may be electrically connected to the first PCB pad B1 of the first PCB pad group BLG of the second PCB test pad portion BP2 by a 4th-3 PCB wiring line PWL4c.

FIG. 11 is a perspective view illustrating structures in current paths used during connection resistance measurement according to the embodiment of FIGS. 8 to 10.

Referring to FIGS. 8 to 11, when a test current is applied to the first input terminal IT, a current path may be formed between the first input terminal IT and the second input terminal OT. When a test current is applied to the first input terminal IT, the test current may flow through a current path including the first PCB pad B1 of the first PCB pad group BLG of the first PCB test pad portion BP1, the first panel pad A1 of the first panel pad group ALG of the first panel test pad portion AP1, the second panel pad A2 of the first panel pad group ALG of the first panel test pad portion AP1, and the second PCB pad B2 of the first PCB pad group BLG of the first PCB test pad portion BP1.

The second PCB pad B2 of the first PCB pad group BLG of the first PCB test pad portion BP1 may be electrically connected to the second PCB pad B2 of the second PCB pad group BRG of the first PCB test pad portion BP1, so that the current path may also include the second PCB pad B2 of the second PCB pad group BRG of the first PCB test pad portion BP1, the second panel pad A2 of the second panel pad group ARG of the first panel test pad portion AP1, the first panel pad A1 of the second panel pad group ARG of the first panel test pad portion AP1, and the first PCB pad B1 of the second PCB pad group BRG of the first PCB test pad portion BP1.

In addition, the first PCB pad B1 of the first PCB pad group BLG of the third PCB test pad portion BP3 adjacent to the first PCB test pad portion BP1 may be electrically connected to the first PCB pad B1 of the second PCB pad group BRG of the first PCB test pad portion BP1, so that the current path may also include the first PCB pad B1 of the first PCB pad group BLG of the third PCB test pad portion BP3, the first panel pad A1 of the first panel pad group ALG of the third panel test pad portion AP3, the second panel pad A2 of the first panel pad group ALG of the third panel test pad portion AP3, and the second PCB pad B2 of the first PCB pad group BLG of the third PCB test pad portion BP3.

In addition, the second PCB pad B2 of the first PCB pad group BLG of the third PCB test pad portion BP3 may be electrically connected to the second PCB pad B2 of the second PCB pad group BRG of the third PCB test pad portion BP3, so that the current path may also include the second PCB pad B2 of the second PCB pad group BRG of the third PCB test pad portion BP3, the second panel pad A2 of the second panel pad group ARG of the third panel test pad portion AP3, the first panel pad A1 of the second panel pad group ARG of the third panel test pad portion AP3, and the first PCB pad B1 of the second PCB pad group BRG of the third PCB test pad portion BP3.

In addition, the first PCB pad B1 of the first PCB pad group BLG of the fourth PCB test pad portion BP4 adjacent to the third PCB test pad portion BP3 may be electrically connected to the first PCB pad B1 of the second PCB pad group BRG of the third PCB test pad portion BP3, so that the current path may also include the first PCB pad B1 of the first PCB pad group BLG of the fourth PCB test pad portion BP4, the first panel pad A1 of the first panel pad group ALG of the fourth panel test pad portion AP4, the second panel pad A2 of the first panel pad group ALG of the fourth panel test pad portion AP4, and the second PCB pad B2 of the first PCB pad group BLG of the fourth PCB test pad portion BP4.

In addition, the second PCB pad B2 of the first PCB pad group BLG of the fourth PCB test pad portion BP4 may be electrically connected to the second PCB pad B2 of the second PCB pad group BRG of the fourth PCB test pad portion BP4, so that the current path may also include the second PCB pad B2 of the second PCB pad group BRG of the fourth PCB test pad portion BP4, the second panel pad A2 of the second panel pad group ARG of the fourth panel test pad portion AP4, the first panel pad A1 of the second panel pad group ARG of the fourth panel test pad portion AP4, and the first PCB pad B1 of the second PCB pad group BRG of the fourth PCB test pad portion BP4.

In addition, the first PCB pad B1 of the first PCB pad group BLG of the second PCB test pad portion BP2 adjacent to the fourth PCB test pad portion BP4 may be electrically connected to the first PCB pad B1 of the second PCB pad group BRG of the fourth PCB test pad portion BP4, so that the current path may also include the first PCB pad B1 of the first PCB pad group BLG of the second PCB test pad portion BP2, the first panel pad A1 of the first panel pad group ALG of the second panel test pad portion AP2, the second panel pad A2 of the first panel pad group ALG of the second panel test pad portion AP2, and the second PCB pad B2 of the first PCB pad group BLG of the second PCB test pad portion BP2.

In addition, the second PCB pad B2 of the first PCB pad group BLG of the second PCB test pad portion BP2 may be electrically connected to the second PCB pad B2 of the second PCB pad group BRG of the second PCB test pad portion BP2, so that the current path may also include the second PCB pad B2 of the second PCB pad group BRG of the second PCB test pad portion BP2, the second panel pad A2 of the second panel pad group ARG of the second panel test pad portion AP2, the first panel pad A1 of the second panel pad group ARG of the second panel test pad portion AP2, and the first PCB pad B1 of the second PCB pad group BRG of the second PCB test pad portion BP2.

That is, the first PCB test pad portion BP1 and the second PCB test pad portion BP2 located at both ends may be electrically connected to each other. For example, the first PCB pad B1 of the first PCB pad group BLG of the second PCB test pad portion BP2 may be electrically connected to the first PCB pad B1 of the second PCB pad group BRG of the first PCB test pad portion BP1. For example, the second input terminal OT connected to the first PCB pad B1 of the second PCB pad group BRG of the second PCB test pad portion BP2 may be electrically connected to the second PCB pad B2 of the first PCB pad group BLG of the first PCB test pad portion BP1. Accordingly, the plurality of PCB test pad portions BP may use a common current source.

In an embodiment, as described with reference to FIGS. 2 to 4, a current source for measuring connection resistance (hereinafter referred to as first connection resistance) between the panel test pad portion AP and the first transmission pad portion FAP and a current source for measuring connection resistance (hereinafter referred to as second connection resistance) between the PCB test pad portion BP and the second transmission pad portion FBP may be connected to each other in a common current structure.

In an embodiment, the second connection resistance between the second transmission pad portion FBP of each of the first to fourth flexible circuit boards 20a, 20b, 20c, and 20d and the PCB test pad portion BP of the printed circuit board 30 may be measured by electrically connecting a current source to allow current from the first input terminal IT connected to the first PCB pad B1 of the first PCB pad group BLG of the first PCB test pad portion BP1 to the second input terminal OT connected to the second PCB pad B2 of the second PCB pad group BRG of the second PCB test pad portion BP2 and connecting a voltmeter to each of the first measurement terminal MT1 connected to the second PCB pad B2 and the second measurement terminal MT2 connected to the third PCB pad B3, in the first PCB pad group BLG and the second PCB pad group BRG of each of the first to fourth PCB test pad portions BP1, BP2, BP3, and BP4, to measure the voltage of the first measurement terminal MT1 and the voltage of the second measurement terminal MT2.

In an embodiment, the first connection resistance between the first transmission pad portion FAP of each of the first to fourth flexible circuit boards 20a, 20b, 20c, and 20d and the panel test pad portion AP of the display panel 10 may be measured by electrically connecting a current source to allow current from the first input terminal IT connected to the first PCB pad B1 of the first PCB pad group BLG of the first PCB test pad portion BP1 to the second input terminal OT connected to the second PCB pad B2 of the second PCB pad group BRG of the second PCB test pad portion BP2 and connecting a voltmeter to each of the second measurement terminal MT2 connected to the third PCB pad B3 and the third measurement terminal MT3 connected to the fourth PCB pad B4, in the first PCB pad group BLG and the second PCB pad group BRG of each of the first to fourth PCB test pad portions BP1, BP2, BP3, and BP4, to measure the voltage of the second measurement terminal MT2 and the voltage of the third measurement terminal MT3.

In an embodiment, as described above, a current source for measuring the first connection resistance between the panel test pad portion AP and the first transmission pad portion FAP and a current source for measuring the second connection resistance between the PCB test pad portion BP and the second transmission pad portion FBP may be connected to each other in a common current structure and the second measurement terminal MT2 may be used for both the measurement of the first connection resistance and the measurement of the second connection resistance, and thus, the number of test terminals TP and the number of transmission pads arranged in the flexible circuit board 20 may be reduced. In addition, as a current source for measuring the connection resistance of the plurality of flexible circuit boards 20 is commonly used, the number of test terminals TP and the number of transmission pads arranged in each second transmission pad portion FBP may be reduced.

In the case of the display apparatus 1 according to an embodiment, the number of test terminals TP used to measure both the first connection resistance between the panel test pad portion AP and the first transmission pad portion FAP and the second connection resistance between the PCB test pad portion BP and the second transmission pad portion FBP may be (6n+2) (where n is the number of flexible circuit boards 20). For example, as shown in FIG. 8, in the case of an embodiment in which the number of flexible circuit boards 20 is four, the test terminals TP may include a first input terminal IT, a second input terminal OT, and first to fourth measurement terminal portions MTP1, MTP2, MTP3, and MPT4 each including six measurement terminals, and thus may include a total of 26 test terminals. In the case of a typical 4-terminal measurement in the display apparatus 1 including a plurality of flexible circuit boards 20 as shown in FIG. 1B, 12n or more test terminals (where n is the number of flexible circuit boards 20) are required to measure the first connection resistance and the second connection resistance for each flexible circuit board 20. However, in the display apparatus 1 according to the present embodiment, by reducing the number of test terminals TP for measuring both the first and second connection resistances of each of the plurality of flexible circuit boards 20 to (6n+2) and thus reducing space occupied by the test terminals TP on the printed circuit board 30, restrictions on the design and arrangement of test pads may be dramatically reduced, and the printed circuit board 30 may be miniaturized.

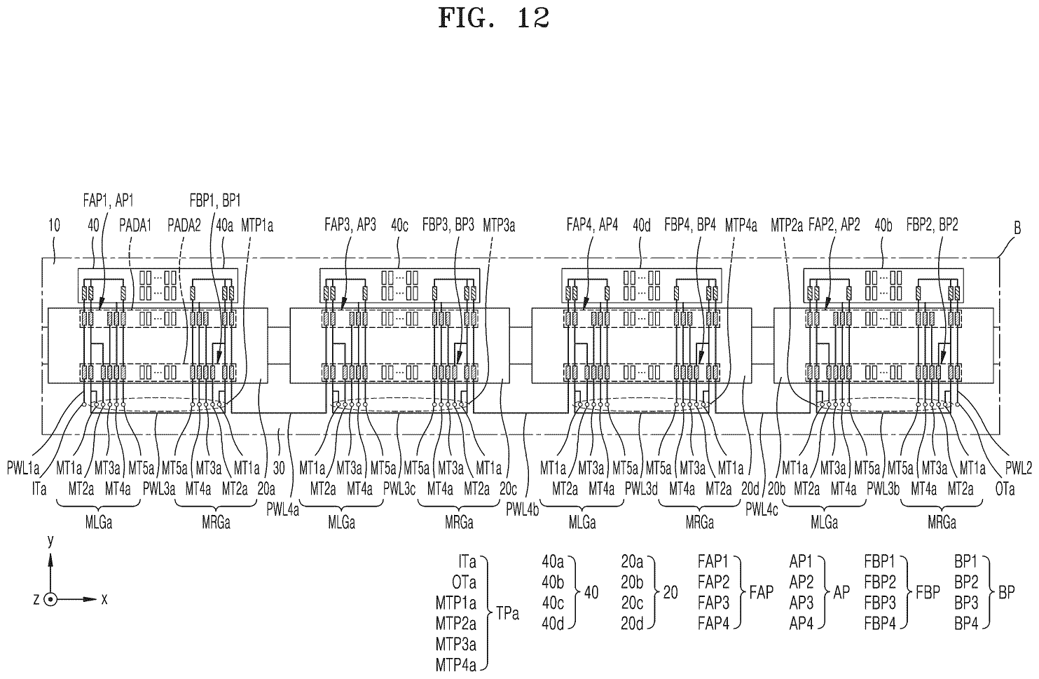

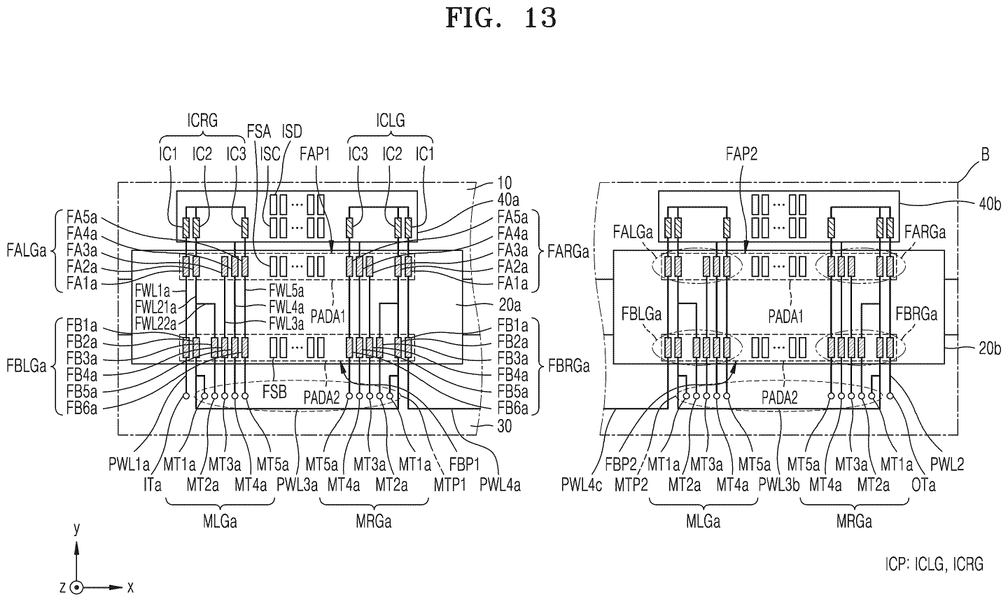

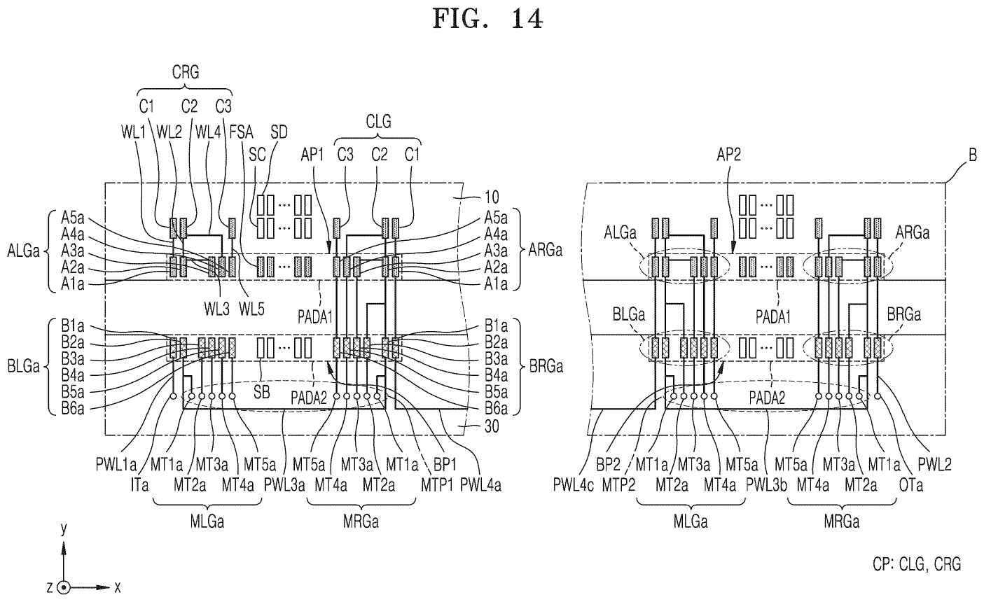

FIG. 12 is an enlarged view of the area ‘B’ of FIG. 1B according to an embodiment. FIG. 13 is an enlarged view of an embodiment of an area corresponding to the first flexible circuit board 20a and the second flexible circuit board 20b in FIG. 12. FIG. 14 is an enlarged view of FIG. 13 excluding the first and second flexible circuit boards 20a and 20b and the first and second integrated circuit chips 40a and 40b.

The embodiments shown in FIGS. 12 to 14 contain components that have the same or similar reference numbers to components shown in FIGS. 2 to 10 and that are described above with reference to FIGS. 2 to 10. The description below may omit redundant descriptions and focus on differences between components shown in FIGS. 12 to 14 and components already described above.

Referring to FIGS. 12 to 14, each of the first to fourth integrated circuit chips 40a, 40b, 40c, and 40d may further include an IC test pad portion ICP. The display panel 10 may further include IC transmission pad portions CP electrically connected respectively to the IC test pad portions ICP of the first to fourth integrated circuit chips 40a, 40b, 40c, and 40d. The IC transmission pad portions CP of the display panel 10 may respectively overlap the IC test pad portions ICP of the integrated circuit chip 40.

The IC test pad portion ICP of each of the first to fourth integrated circuit chips 40a, 40b, 40c, and 40d may include a first IC test pad group ICLG and a second IC test pad group ICRG, each including a plurality of IC test pads. In an embodiment, the first IC test pad group ICLG and the second IC test pad group ICRG may each include a first IC test pad IC1, a second IC test pad IC2, and a third IC test pad IC3. The first IC test pad IC1, the second IC test pad IC2, and the third IC test pad IC3 may be connected (e.g., electrically connected) to each other.

Each of the IC transmission pad portions CP corresponding to the first to fourth integrated circuit chips 40a, 40b, 40c, and 40d, respectively may include a first IC transmission pad group CLG and a second IC transmission pad group CRG. In an embodiment, the first IC transmission pad group CLG and the second IC transmission pad group CRG may each include a first IC transmission pad C1, a second IC transmission pad C2, and a third IC transmission pad C3. The first IC transmission pad C1 may overlap the first IC test pad IC1, the second IC transmission pad C2 may overlap the second IC test pad IC2, and the third IC transmission pad C3 may overlap the third IC test pad IC3.

The display panel 10 may include a plurality of panel test pad portions APa. For example, the display panel 10 may include a first panel test pad portion AP1a, a second panel test pad portion AP2a, a third panel test pad portion AP3a, and a fourth panel test pad portion AP4a. Each of the first to fourth panel test pad portions AP1a, AP2a, AP3a, and AP4a may include a first panel pad group ALGa and a second panel pad group ARGa. In an embodiment, the first panel pad group ALGa and the second panel pad group ARGa may each include a first panel pad A1a, a second panel pad A2a, a third panel pad A3a, a fourth panel pad A4a, and a fifth panel pad A5a.

The first to fourth panel test pad portions AP1a, AP2a, AP3a, and AP4a and IC test pad portions ICP respectively corresponding to the first to fourth flexible circuit boards 20a, 20b, 20c, and 20d have substantially the same structure, and thus, for convenience of description, the description below focuses on the components and connection relationships of the first panel test pad portion AP1a and IC test pad portion ICP corresponding to the first flexible printed circuit board 20a.

As shown in FIG. 14, the first panel pad A1a may be electrically connected to the first IC transmission pad C1 by a first panel wiring line WL1. The second panel pad A2a may be electrically connected to the second IC transmission pad C2 by a second panel wiring line WL2. The third panel pad A3a may be electrically connected to the second panel pad A2a by a third panel wiring line WL3. In an embodiment, the third panel wiring line WL3 may connect the second panel pad A2a and the third panel pad A3a to each other. In an embodiment, the third panel pad A3a may be electrically connected to the second IC transmission pad C2 through the third panel wiring line WL3 and the second panel pad A2a. The fourth panel pad A4a may be electrically connected to the second IC transmission pad C2 by a fourth panel wiring line WL4. The fifth panel pad A5a may be electrically connected to the third IC transmission pad C3 by a fifth panel wiring line WL5. The first panel wiring line WL1, the second panel wiring line WL2, the third panel wiring line WL3, the fourth panel wiring line WL4, and the fifth panel wiring line WL5 may be disposed in or on the display panel 10.

The printed circuit board 30 may include a plurality of PCB test pad portions BPa and test terminals TPa. For example, the printed circuit board 30 may include a first PCB test pad portion BP1, a second PCB test pad portion BP2, a third PCB test pad portion BP3, and a fourth PCB test pad portion BP4. The PCB test pad portion BPa may include a first PCB pad group BLGa and a second PCB pad group BRGa, each including a plurality of PCB pads. In an embodiment, the first PCB pad group BLGa and the second PCB pad group BRGa may each include a first PCB pad B1a, a second PCB pad B2a, a third PCB pad B3a, a fourth PCB pad B4a, a fifth PCB pad B5a, and a sixth PCB pad B6a.

The test terminals TPa may include a plurality of measurement terminal portions respectively electrically connected to the first input terminal ITa, the second input terminal OTa, and a plurality of PCB test pad portions BPa. For example, the test terminals TPa may include a first measurement terminal portion MTP1a electrically connected to the first PCB test pad portion BP1, a second measurement terminal portion MTP2a electrically connected to the second PCB test pad portion BP2, a third measurement terminal portion MTP3a electrically connected to the third PCB test pad portion BP3, and a fourth measurement terminal portion MTP4a electrically connected to the fourth PCB test pad portion BP4. Each of the first to fourth measurement terminal portions MTP1a, MTP2a, MTP3a, and MTP4a may include a first measurement terminal group MLG and a second measurement terminal group MRG.

The first input terminal ITa may be electrically connected to the first PCB pad B1a of the first PCB pad group BLG of the first PCB test pad portion BP1. In an embodiment, the first input terminal ITa may be electrically connected to the first PCB pad B1a of the first PCB pad group BLGa of the first PCB test pad portion BP1 by a first PCB wiring line PWL1a.

The second input terminal OTa may be electrically connected to the first PCB pad B1a of the second PCB pad group BRGa of the second PCB test pad portion BP2. In an embodiment, the second input terminal OTa may be electrically connected to the first PCB pad B1a of the first PCB pad group BLGa of the first PCB test pad portion BP1 by a second PCB wiring line PWL2a.

The first measurement terminal group MLGa of each of the first to fourth measurement terminal portions MTP1a, MTP2a, MTP3a, and MTP4a may be electrically connected to the first PCB pad group BLGa of a corresponding PCB test pad portion BPa. The second measurement terminal group MRGa of each of the first to fourth measurement terminal portions MTP1a, MTP2a, MTP3a, and MTP4a may be electrically connected to the second PCB pad group BRGa of a corresponding PCB test pad portion BPa.

The first measurement terminal group MLGa and the second measurement terminal group MRGa may each include a first measurement terminal MT1a, a second measurement terminal MT2a, a third measurement terminal MT3a, a fourth measurement terminal MT4a, and a fifth measurement terminal MT5a. The first measurement terminal group MLGa may include a first measurement terminal MT1a electrically connected to the second PCB pad B2a of the first PCB pad group BLGa, a second measurement terminal MT2a electrically connected to the third PCB pad B3a of the first PCB pad group BLGa, a third measurement terminal MT3a electrically connected to the fourth PCB pad B4a of the first PCB pad group BLGa, a fourth measurement terminal MT4a electrically connected to the fifth PCB pad B5a of the first PCB pad group BLGa, and a fifth measurement terminal MT5a electrically connected to the sixth PCB pad B6a of the first PCB pad group BLGa. The second measurement terminal group MRGa may include a first measurement terminal MT1a electrically connected to the second PCB pad B2a of the second PCB pad group BRGa, a second measurement terminal MT2a electrically connected to the third PCB pad B3a of the second PCB pad group BRGa, a third measurement terminal MT3a electrically connected to the fourth PCB pad B4a of the second PCB pad group BRGa, a fourth measurement terminal MT4a electrically connected to the fifth PCB pad B5a of the second PCB pad group BRGa, and a fifth measurement terminal MT5a electrically connected to the sixth PCB pad B6a of the second PCB pad group BRGa.

Each of the plurality of flexible circuit boards 20 may include a first transmission pad portion FAPa disposed at one end thereof and a second transmission pad portion FBPa disposed at the other end. That is, the first to fourth flexible circuit boards 20a, 20b, 20c, and 20d may respectively include first transmission pad portions FAP1, FAP2, FAP3, and FAP4 disposed at ends thereof and second transmission pad portions FBP1, FBP2, FBP3, and FBP4 disposed at the other ends.

Each of the first transmission pad portions FAP1, FAP2, FAP3, and FAP4 may include a 1st-1 transmission pad group FALGa and a 1st-2 transmission pad group FARGa. The 1st-1 transmission pad group FALGa and the 1st-2 transmission pad group FARGa may each include a 1st-1 transmission pad FA1a, a 1st-2 transmission pad FA2a, a 1st-3 transmission pad FA3a, a 1st-4 transmission pad FA4a, and a 1st-5 transmission pad FA5a.

Each of the second transmission pad portions FBP1, FBP2, FBP3, and FBP4 may include a 2nd-1 transmission pad group FBLGa and a 2nd-2 transmission pad group FBRGa. In an embodiment, the 2nd-1 transmission pad group FBLGa and the 2nd-2 transmission pad group FBRGa may each include a 2nd-1 transmission pad FB1a, a 2nd-2 transmission pad FB2a, a 2nd-3 transmission pad FB3a, a 2nd-4 transmission pad FB4a, a 2nd-5 transmission pad FB5a, and a 2nd-6 transmission pad FB6a.

The first transmission pad portions FAPa of the plurality of flexible circuit boards 20 may respectively be electrically connected to the corresponding panel test pad portions APa of the display panel 10. The second transmission pad portions FBPa of the first to fourth flexible circuit boards 20a, 20b, 20c, and 20d may respectively be electrically connected to the corresponding PCB test pad portions BPa of the printed circuit board 30.

The first to fourth flexible circuit boards 20a, 20b, 20c, and 20d may each include a first wiring line FWL1a, a second wiring line FWL21a, a third wiring line FWL3a, a fourth wiring line FWL4a, a fifth wiring line FWL5a, and a sub-wiring line FWL22a. Because the first to fourth flexible circuit boards 20a, 20b, 20c, and 20d include the same configuration and the connection relationships of the first to fourth flexible circuit boards 20a, 20b, 20c, and 20d are substantially the same, for convenience of description, the description below focuses on the first flexible circuit board 20a as shown in FIG. 13.

The 2nd-1 transmission pad FB1a may be electrically connected to the 1st-1 transmission pad FA1a through the first wiring line FWL1a. The 2nd-2 transmission pad FB2a may be electrically connected to the 1st-2 transmission pad FA2 by the second wiring line FWL21a. The 2nd-3 transmission pad FB3a may be electrically connected to the 1st-2 transmission pad FA2a by the sub-wiring line FWL22a connected to the second wiring line FWL21a. In an embodiment, the 2nd-3 transmission pad FB3a may be electrically connected to the 1st-2 transmission pad FA2a through the sub-wiring line FWL22a and the second wiring line FWL21a. The 2nd-4 transmission pad FB4a may be electrically connected to the 1st-3 transmission pad FA3a by the third wiring line FWL3a. The 2nd-5 transmission pad FB5a may be electrically connected to the 1st-4 transmission pad FA4a by the fourth wiring line FWL4a. The 2nd-6 transmission pad FB6a may be electrically connected to the 1st-5 transmission pad FA5a by the fifth wiring line FWL5a. The first wiring line FWL1a, the second wiring line FWL21a, the sub-wiring line FWL22a, the third wiring line FWL3a, the fourth wiring line FWL4a, and the fifth wiring line FWL5a may be disposed on the flexible circuit board 20.

The first wiring line FWL1a, the second wiring line FWL21a, the third wiring line FWL3a, the fourth wiring line FWL4a, the fifth wiring line FWL5a, and the sub-wiring line FWL22a may each include a conductive material having low resistance. In an embodiment, the resistance of each of the first wiring line FWL1a, the second wiring line FWL21a, the third wiring line FWL3a, the fourth wiring line FWL4a, the fifth wiring line FWL5a, and the sub-wiring line FWL22a may be less than the resistance of each of the first panel wiring line WL1, the second panel wiring line WL2, the third panel wiring line WL3, the fourth panel wiring line WL4, and the fifth panel wiring line WL5. For example, the first wiring line FWL1a, the second wiring line FWL21a, the third wiring line FWL3a, the fourth wiring line FWL4a, the fifth wiring line FWL5a, and the sub-wiring line FWL22a may each include a conductive material including copper (Cu).

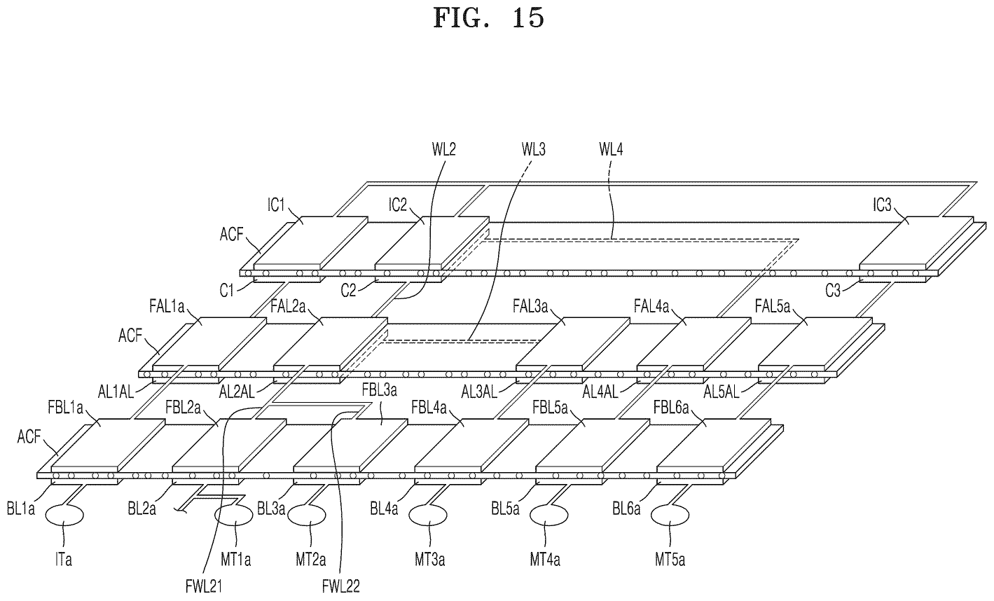

The transmission pads of the first transmission pad portion FAPa may respectively be electrically connected to the panel pads of the panel test pad portion APa by an anisotropic conductive film ACF, as shown in FIG. 15. Likewise, the transmission pads of the second transmission pad portion FBPa may respectively be electrically connected to the PCB pads of the PCB test pad portion BPa by the anisotropic conductive film ACF. Likewise, the transmission pads of the IC transmission pad portion CP may respectively be electrically connected to the IC test pads of the IC test pad portion ICP by the anisotropic conductive film ACF.

In an embodiment, the electrical connection relationship between pads of the IC test pad portion ICP, the IC transmission pad portion CP, the panel test pad portion APa, the first transmission pad portion FAPa, the second transmission pad portion FBPa, and the PCB test pad portion BPa, which correspond to each other, may be the same as that in the embodiment described with reference to FIGS. 5 and 6.

In an embodiment, similar to the embodiment of FIGS. 8 to 10, in each of the PCB test pad portions BPa, the second PCB pad B2a of the first PCB pad group BLGa may be electrically connected to the second PCB pad B2a of the second PCB pad group BRGa of the first PCB test pad portion BP1.

In an embodiment, similar to the embodiment of FIGS. 8 to 10, the first PCB pad B1a of the second PCB pad group BRGa of any one of the PCB test pad portions BPa may be electrically connected to the first PCB pad B1a of the first PCB pad group BLGa of another PCB test pad portion BPa adjacent to the one of the PCB test pad portions BPa.

FIG. 15 is a perspective view illustrating structures in current paths used during connection resistance measurement according to the embodiment of FIGS. 12 to 14.

Referring to FIGS. 12 to 15, when a test current is applied to the first input terminal ITa, a current path may be formed between the first input terminal ITa and the second input terminal OTa.

In an embodiment, when a test current is applied to the first input terminal ITa, a test current may flow through a current path including the first PCB pad B1a of the first PCB pad group BLGa of the first PCB test pad portion BP1, the first panel pad A1a of the first panel pad group ALGa of the first panel test pad portion AP1, the first IC test pad IC1 and the second IC test pad IC2 of the IC test pad portion ICP corresponding to the first panel pad group ALGa of the first panel test pad portion AP1, the second panel pad A2a of the first panel pad group ALGa of the first panel test pad portion AP1, and the second PCB pad B2a of the first PCB pad group BLGa of the first PCB test pad portion BP1.

In addition, the second PCB pad B2a of the first PCB pad group BLGa of the first PCB test pad portion BP1 may be electrically connected to the second PCB pad B2a of the second PCB pad group BRGa of the first PCB test pad portion BP1, so that test current may also flow through a current path including the second PCB pad B2a of the second PCB pad group BRGa of the first PCB test pad portion BP1, the second panel pad A2a of the second panel pad group ARGa of the first panel test pad portion AP1, the second IC test pad IC2 and the first IC test pad IC1 of the IC test pad portion ICP corresponding to the second panel pad group ARGa of the first panel test pad portion AP1, the first panel pad A1a of the second panel pad group ARGa of the first panel test pad portion AP1, and the first PCB pad B1a of the second PCB pad group BRGa of the first PCB test pad portion BP1.

In addition, the first PCB pad B1a of the first PCB pad group BLGa of the third PCB test pad portion BP3 may be electrically connected to the first PCB pad B1a of the second PCB pad group BRGa of the first PCB test pad portion BP1, so that test current may also flow through a current path including the first PCB pad B1a of the first PCB pad group BLGa of the third PCB test pad portion BP3, the first panel pad A1a of the first panel pad group ALGa of the third panel test pad portion AP3a, the first IC test pad IC1 and the second IC test pad IC2 of the IC test pad portion ICP corresponding to the first panel pad group ALGa of the third panel test pad portion AP3a, the second panel pad A2a of the first panel pad group ALGa of the third panel test pad portion AP3a, and the second PCB pad B2a of the first PCB pad group BLGa of the third PCB test pad portion BP3.

In addition, the second PCB pad B2a of the first PCB pad group BLGa of the third PCB test pad portion BP3 may be electrically connected to the second PCB pad B2a of the second PCB pad group BRGa of the third PCB test pad portion BP3, so that test current may also flow through a current path including the second PCB pad B2a of the second PCB pad group BRGa of the third PCB test pad portion BP3, the second panel pad A2a of the second panel pad group ARGa of the third panel test pad portion AP3, the second IC test pad IC2 and the first IC test pad IC1 of the IC test pad portion ICP corresponding to the second panel pad group ARGa of the third panel test pad portion AP3, the first panel pad A1a of the second panel pad group ARGa of the third panel test pad portion AP3, and the first PCB pad B1a of the second PCB pad group BRGa of the third PCB test pad portion BP3.

In addition, the first PCB pad B1a of the first PCB pad group BLGa of the fourth PCB test pad portion BP4 adjacent to the third PCB test pad portion BP3 may be electrically connected to the first PCB pad B1a of the second PCB pad group BRGa of the third PCB test pad portion BP3a, so that test current may also flow through a current path including the first PCB pad B1a of the first PCB pad group BLGa of the fourth PCB test pad portion BP4, the first panel pad A1a of the first panel pad group ALGa of the fourth panel test pad portion AP4, the first IC test pad IC1 and the second IC test pad IC2 of the IC test pad portion ICP corresponding to the first panel pad group ALGa of the fourth panel test pad portion AP4, the second panel pad A2a of the first panel pad group ALG of the fourth panel test pad portion AP4, and the second PCB pad B2a of the first PCB pad group BLGa of the fourth PCB test pad portion BP4.

In addition, the second PCB pad B2a of the first PCB pad group BLGa of the fourth PCB test pad portion BP4 may be electrically connected to the second PCB pad B2a of the second PCB pad group BRGa of the fourth PCB test pad portion BP4, so that test current may also flow through a current path including the second PCB pad B2a of the second PCB pad group BRGa of the fourth PCB test pad portion BP4, the second panel pad A2a of the second panel pad group ARGa of the fourth panel test pad portion AP4, the second IC test pad IC2 and the first IC test pad IC1 of the IC test pad portion ICP corresponding to the second panel pad group ARGa of the fourth panel test pad portion AP4, the first panel pad A1a of the second panel pad group ARGa of the fourth panel test pad portion AP4, and the first PCB pad B1a of the second PCB pad group BRGa of the fourth PCB test pad portion BP4.

In addition, the first PCB pad B1a of the first PCB pad group BLGa of the second PCB test pad portion BP2a adjacent to the fourth PCB test pad portion BP4 may be electrically connected to the first PCB pad B1a of the second PCB pad group BRGa of the fourth PCB test pad portion BP4, so that test current may also flow through a current path including the first PCB pad B1a of the first PCB pad group BLGa of the second PCB test pad portion BP2, the first panel pad A1a of the first panel pad group ALGa of the second panel test pad portion AP2, the first IC test pad IC1 and the second IC test pad IC2 of the IC test pad portion ICP corresponding to the first panel pad group ALGa of the second panel test pad portion AP2, the second panel pad A2a of the first panel pad group ALGa of the second panel test pad portion AP2, and the second PCB pad B2a of the first PCB pad group BLGa of the second PCB test pad portion BP2.

In addition, the second PCB pad B2a of the first PCB pad group BLGa of the second PCB test pad portion BP2 may be electrically connected to the second PCB pad B2a of the second PCB pad group BRGa of the second PCB test pad portion BP2, so that test current may also flow through a current path including the second PCB pad B2a of the second PCB pad group BRGa of the second PCB test pad portion BP2, the second panel pad A2a of the second panel pad group ARGa of the second panel test pad portion AP2, the second IC test pad IC2 and the first IC test pad IC1 of the IC test pad portion ICP corresponding to the second panel pad group ARGa of the second panel test pad portion AP2, the first panel pad A1a of the second panel pad group ARGa of the second panel test pad portion AP2, and the first PCB pad B1a of the second PCB pad group BRGa of the second PCB test pad portion BP2.

That is, the first PCB test pad portion BP1 and the second PCB test pad portion BP2 located at both ends may be electrically connected to each other. For example, the first PCB pad B1 of the first PCB pad group BLGa of the second PCB test pad portion BP2 may be electrically connected to the first PCB pad B1a of the second PCB pad group BRGa of the first PCB test pad portion BP1. For example, the second input terminal OTa connected to the first PCB pad B1a of the second PCB pad group BRGa of the second PCB test pad portion BP2 may be electrically connected to the second PCB pad B2a of the first PCB pad group BLGa of the first PCB test pad portion BP1. Accordingly, the plurality of PCB test pad portions BP may use a common current source.

In an embodiment, the second connection resistance between the second transmission pad portion FBPa of the flexible circuit board 20 and the PCB test pad portion BPa of the printed circuit board 30 may be measured by electrically connecting a current source to the first input terminal ITa connected to the first PCB pad B1a of the first PCB pad group BLGa of the first PCB test pad portion BP1 and the second input terminal OTa connected to the second PCB pad B2a of the second PCB pad group BRGa of the second PCB test pad portion BP2 to apply a current and connecting a voltmeter to each of the first measurement terminal MT1a connected to the second PCB pad B2a and the second measurement terminal MT2a connected to the third PCB pad B3a, in the first PCB pad group BLGa and the second PCB pad group BRGa of each of the first to fourth PCB test pad portions BP1, BP2, BP3, and BP4, to measure the voltage of the first measurement terminal MT1a and the voltage of the second measurement terminal MT2a.

In an embodiment, the first connection resistance between the first transmission pad portion FAPa of the flexible circuit board 20 and the panel test pad portion AP of the display panel 10 may be measured by electrically connecting a current source to allow current from the first input terminal ITa connected to the first PCB pad B1a of the first PCB pad group BLGa of the first PCB test pad portion BP1 to the second input terminal OTa connected to the second PCB pad B2a of the second PCB pad group BRGa of the second PCB test pad portion BP2 and connecting a voltmeter to each of the second measurement terminal MT2a connected to the third PCB pad B3a and the third measurement terminal MT3a connected to the fourth PCB pad B4, in the first PCB pad group BLGa and the second PCB pad group BRGa of each of the first to fourth PCB test pad portions BP1, BP2, BP3, and BP4, to measure the voltage of the second measurement terminal MT2a and the voltage of the third measurement terminal MT3a.

In an embodiment, the third connection resistance between the IC test pad portion ICP of the integrated circuit chip 40 and the IC transmission pad portion CP of the display panel 10 may be measured by electrically connecting a current source to allow current from the first input terminal ITa connected to the first PCB pad B1a of the first PCB pad group BLGa of the first PCB test pad portion BP1 to the second input terminal OTa connected to the second PCB pad B2a of the second PCB pad group BRGa of the second PCB test pad portion BP2 and connecting a voltmeter to each of the fourth measurement terminal MT4a connected to the fifth PCB pad B5a and the fifth measurement terminal MT5a connected to the sixth PCB pad B6, in the first PCB pad group BLGa and the second PCB pad group BRGa of each of the first to fourth PCB test pad portions BP1, BP2, BP3, and BP4, to measure the voltage of the fourth measurement terminal MT4a and the voltage of the fifth measurement terminal MT5a.

In an embodiment, a current source for measuring the third connection resistance between the IC transmission pad portion CP and the IC test pad portion ICP, a current source for measuring the first connection resistance between the panel test pad portion AP and the first transmission pad portion FAP, and a current source for measuring the second connection resistance between the PCB test pad portion BP and the second transmission pad portion FBP may be connected to each other in a common current structure and the second measurement terminal MT2 may be used for both the measurement of the first connection resistance and the measurement of the second connection resistance, and thus, the number of test terminals TP and the number of transmission pads arranged in the flexible circuit board 20 may be reduced. In addition, as a current source for measuring the connection resistance of the plurality of flexible circuit boards 20 is commonly used, the number of test terminals TP and the number of transmission pads arranged in each second transmission pad portion FBP may be reduced.

In the case of the display apparatus 1 according to an embodiment, the number of test terminals TPa required to measure the first connection resistance between the panel test pad portion APa and the first transmission pad portion FAPa, the second connection resistance between the PCB test pad portion BPa and the second transmission pad portion FBPa, and the third connection resistance between the IC transmission pad portion CP and the IC test pad portion ICP may be (10n+2) (where n is the number of flexible circuit boards 20). For example, as shown in FIG. 12, in the case of an embodiment in which the number of flexible circuit boards 20 is four, the test terminals TP may include a first input terminal ITa, a second input terminal OTa, and first to fourth measurement terminal portions MTP1, MTP2, MTP3, and MPT4 each including 10 measurement terminals, and thus may include a total of 42 test terminals.

In the display apparatus 1 according to the present embodiment, by reducing the number of test terminals TP for measuring all of the first to third connection resistances of each of the plurality of flexible circuit boards 20 to (10n+2) and thus reducing a space occupied by the test terminals TP on the printed circuit board 30, restrictions on the design and arrangement of test pads may be dramatically reduced, and the printed circuit board 30 may be miniaturized.

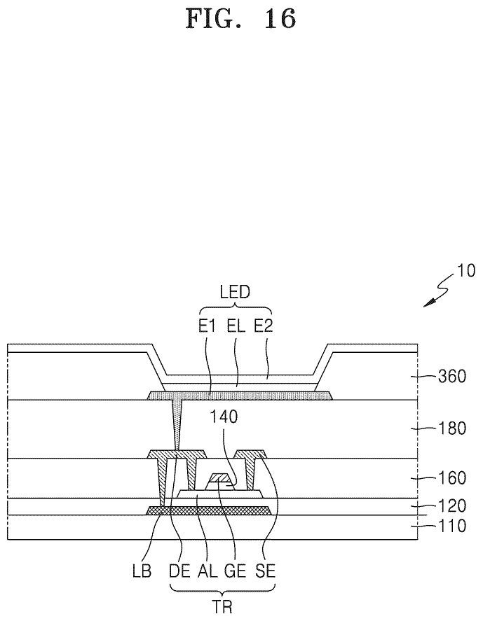

FIG. 16 is a schematic cross-sectional view within a display area of a display panel 10 included in a display apparatus according to an embodiment.

Referring to FIG. 16, the display panel 10 includes a substrate 110 and various layers and wiring lines located thereon. The substrate 110 may include an insulating material, such as glass or plastic. For example, the substrate 110 may have a multi-layered structure including two resin layers with an inorganic material layer therebetween.

A light-blocking layer LB may be on the substrate 110. The light-blocking layer LB may block external light from reaching a semiconductor layer AL of a transistor TR, thereby preventing or reducing degradation of the characteristics of the semiconductor layer AL. The light-blocking layer LB may be an electrode that receives a certain voltage or a wiring line that transmits a certain voltage in the display panel 10. The light-blocking layer LB may include copper (Cu), aluminum (Al), silver (Ag), chromium (Cr), titanium (Ti), tantalum (Ta), or the like and may have a single-layered structure or a multi-layered structure.

A barrier layer (not shown) that may include an inorganic insulating material, such as silicon nitride (SiNₓ), silicon oxide (SiOₓ), or silicon oxynitride (SiOₓN_{y}), may be disposed between the substrate 110 and the light-blocking layer LB. The barrier layer may have a single-layered structure or a multi-layered structure.

A buffer layer 120 may be located on the light-blocking layer LB. The buffer layer 120 may prevent impurities from diffusing from the substrate 110 to the semiconductor layer AL and may provide a flattened or planarized upper surface. The buffer layer 120 may include an inorganic insulating material, such as silicon nitride (SiNₓ), silicon oxide (SiOₓ), or silicon oxynitride (SiOₓN_{y}), and may have a single-layer structure or a multi-layer structure.

The semiconductor layer AL may be on the buffer layer 120. The semiconductor layer AL may include a channel region of the transistor TR and a source region and a drain region on opposite sides of the channel region. The semiconductor layer AL may include one of amorphous silicon, polycrystalline silicon, and oxide semiconductor. When the semiconductor layer AL includes an oxide semiconductor, the semiconductor layer AL may include at least one of zinc (Zn), indium (In), gallium (Ga), and tin (Sn). For example, the semiconductor layer AL may include indium-gallium-zinc oxide (IGZO).

A gate insulating layer 140 may be located on the semiconductor layer AL. The gate insulating layer 140 may include an inorganic insulating material, such as silicon nitride (SiNₓ), silicon oxide (SiOₓ), or silicon oxynitride (SiOₓN_{y}), and may have a single-layer structure or a multi-layer structure.

A gate electrode GE of the transistor TR may be located on the gate insulating layer 140. The gate electrode GE may include molybdenum (Mo), aluminum (Al), copper (Cu), titanium (Ti), or the like.

An interlayer insulating layer 160 may be located on the gate electrode GE. The interlayer insulating layer 160 may include an inorganic insulating material, such as silicon nitride (SiNₓ), silicon oxide (SiOₓ), or silicon oxynitride (SiOₓN_{y}), and may have a single-layer structure or a multi-layer structure.

A source electrode SE and drain electrode DE of the transistor TR may be on the interlayer insulating layer 160. If necessary, the drain electrode DE may be connected to the light-blocking layer LB through a contact hole formed in the interlayer insulating layer 160 and the buffer layer 120. The source electrode SE and the drain electrode DE may each include aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), copper (Cu), or the like.

A planarization layer 180 may be located on the source electrode SE and the drain electrode DE. The planarization layer 180 may be an organic layer. For example, the planarization layer 180 may include an organic insulating material, such as a general-purpose polymer (e.g., polymethyl methacrylate or polystyrene), a polymer derivative having a phenol-based group, an acryl-based polymer, an imide-based polymer, polyimide, or a siloxane-based polymer.

A pixel electrode E1 of a light-emitting diode LED may be on the planarization layer 180. The pixel electrode E1 may be connected to the drain electrode DE through a contact hole formed in the planarization layer 180. The pixel electrode E1 may include a reflective conductive material or a semi-transmissive conductive material or may include a transparent conductive material. For example, the pixel electrode E1 may include a transparent conductive material, such as indium tin oxide (ITO) or indium zinc oxide (IZO), or may include a metal, such as lithium (Li), calcium (Ca), aluminum (Al), silver (Ag), magnesium (Mg) or gold (Au), or a metal alloy.

A pixel-defining layer 360 having an opening that overlaps the pixel electrode E1 may be located on the planarization layer 180. The pixel-defining layer 360 may include an organic insulating material, such as an acryl-based polymer or an imide-based polymer.

An emission layer EL may be located on the pixel electrode E1. In addition to the emission layer EL, at least one of a hole injection layer, a hole transport layer, an electron transport layer, and an electron injection layer may be on the pixel electrode E1.

A common electrode E2 may be located on the emission layer EL. The common electrode E2 may be integrally formed as one body with respect to several pixels. The common electrode E2 may include a metal having a low work function, such as calcium (Ca), barium (Ba), magnesium (Mg), aluminum (Al), or silver (Ag), or a metal alloy, and may be formed as a thin layer and have light transparency. If necessary, the common electrode E2 may include a transparent conductive oxide, such as indium tin oxide (ITO) or indium zinc oxide (IZO).

A light-emitting diode LED, such as an organic light-emitting diode, may be located in each pixel. Each light-emitting diode LED may include a pixel electrode E1, an emission layer EL, and the common electrode E2 as described above. The pixel electrode E1 may be an anode of the light-emitting diode LED, and the common electrode E2 may be a cathode of the light-emitting diode LED.

An encapsulation layer (not shown) may be on the common electrode E2. The encapsulation layer may be a thin-film encapsulation layer in which one or more inorganic layers and one or more organic layers are stacked.

According to the one or more embodiments, a display apparatus may permit efficient testing of the bonding state between a flexible circuit board and a display panel and the bonding state between the flexible circuit board and a printed circuit board. However, the above effects are examples, and the scope of the disclosure is not limited by these effects.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus comprising:
a display panel including a panel test pad portion;
a printed circuit board including a printed circuit board (PCB) test pad portion and test terminals; and
a flexible circuit board including a first transmission pad portion electrically connected to the panel test pad portion and a second transmission pad portion electrically connected to the PCB test pad portion,
wherein the panel test pad portion includes a first panel pad, a second panel pad, and a third panel pad,
the PCB test pad portion includes a first PCB pad electrically connected to the first panel pad, a second PCB pad electrically connected to the second panel pad, a third PCB pad electrically connected to the second panel pad, and a fourth PCB pad electrically connected to the third panel pad, and
the test terminals include a first input terminal electrically connected to the first PCB pad, a second input terminal electrically connected to the second PCB pad, a first measurement terminal electrically connected to the second PCB pad, a second measurement terminal electrically connected to the third PCB pad, and a third measurement terminal electrically connected to the fourth PCB pad.

2. The display apparatus of claim 1, wherein, when a test current is applied to the first input terminal, the test current flows through a current path including the first PCB pad, the first panel pad, the second panel pad, and the second PCB pad.

3. The display apparatus of claim 1, wherein the first transmission pad portion includes a 1st-1 transmission pad overlapping the first panel pad, a 1st-2 transmission pad overlapping the second panel pad, and a 1st-3 transmission pad overlapping the third panel pad, and
the second transmission pad portion includes a 2nd-1 transmission pad overlapping the first PCB pad, a 2nd-2 transmission pad overlapping the second PCB pad, a 2nd-3 transmission pad overlapping the third PCB pad, and a 2nd-4 transmission pad overlapping the fourth PCB pad, and
wherein the 2nd-1 transmission pad is electrically connected to the 1st-1 transmission pad by a first wiring line, the 2nd-2 transmission pad is electrically connected to the 1st-2 transmission pad by a second wiring line, the 2nd-3 transmission pad is electrically connected to the 1st-2 transmission pad by the second wiring line and a sub-wiring line connected to the second wiring line, and the 2nd-4 transmission pad is electrically connected to the 1st-3 transmission pad by a third wiring line.

4. The display apparatus of claim 1, further comprising an integrated circuit chip including an integrated circuit (IC) test pad portion,
wherein the display panel further includes an IC transmission pad portion electrically connected to the IC test pad portion, and the IC test pad portion includes a first IC test pad, a second IC test pad, and a third IC test pad, and
wherein the first IC test pad is electrically connected to the first panel pad, and the second IC test pad is electrically connected to the second panel pad.

5. The display apparatus of claim 4, wherein, when a test current is applied to the first input terminal, the test current flows through a current path including the first PCB pad, the first panel pad, the first IC test pad, the second IC test pad, the second panel pad, and the second PCB pad.

6. The display apparatus of claim 4, wherein the IC transmission pad portion includes a first IC transmission pad overlapping the first IC test pad, a second IC transmission pad overlapping the second IC test pad, and a third IC transmission pad overlapping the third IC test pad, and
the panel test pad portion further includes a fourth panel pad and a fifth panel pad,
wherein the first panel pad is electrically connected to the first IC transmission pad by a first panel wiring line, the second panel pad is electrically connected to the second IC transmission pad by a second panel wiring line, the third panel pad is electrically connected to the second IC transmission pad by the second panel pad and a third panel wiring line that electrically connects the second panel pad to the third panel pad, the fourth panel pad is electrically connected to the second IC transmission pad by a fourth panel wiring line, and the fifth panel pad is electrically connected to the third IC transmission pad by a fifth panel wiring line.

7. The display apparatus of claim 6, wherein the PCB test pad portion further includes a fifth PCB pad electrically connected to the fourth panel pad and a sixth PCB pad electrically connected to the fifth panel pad, and
the test terminals further include a fourth measurement terminal electrically connected to the fifth PCB pad and a fifth measurement terminal electrically connected to the sixth PCB pad.

8. The display apparatus of claim 1, wherein a plurality of panel test pad portions are provided, a plurality of PCB test pad portions are provided, and a plurality of flexible circuit boards are provided,
wherein the plurality of flexible circuit boards are respectively located to correspond to the plurality of panel test pad portions and correspond to the plurality of PCB test pad portions.

9. The display apparatus of claim 8, wherein the first input terminal is electrically connected to the first PCB pad of one PCB test pad portion among the plurality of PCB test pad portions by a first PCB wiring line, and
the second input terminal is electrically connected to the first PCB pad of another PCB test pad portion among the plurality of PCB test pad portions by a second PCB wiring line.

10. The display apparatus of claim 9, further comprising a plurality of first measurement terminals, a plurality of second measurement terminals, and a plurality of third measurement terminals, which are respectively and electrically connected to the plurality of PCB test pad portions.

11. A display apparatus comprising:
a display panel including a panel test pad portion;
a printed circuit board including a printed circuit board (PCB) test pad portion and test terminals; and
a flexible circuit board including a first transmission pad portion electrically connected to the panel test pad portion and a second transmission pad portion electrically connected to the PCB test pad portion,
wherein the panel test pad portion includes a first panel pad and a second panel pad,
the first transmission pad portion includes a 1st-1 transmission pad overlapping the first panel pad and a 1st-2 transmission pad overlapping the second panel pad,
the second transmission pad portion includes a 2nd-1 transmission pad electrically connected to the 1st-1 transmission pad by a first wiring line, a 2nd-2 transmission pad electrically connected to the 1st-2 transmission pad by a second wiring line, and a 2nd-3 transmission pad electrically connected to the 1st-2 transmission pad by the second wiring line and a sub-wiring line connected to the second wiring line,
the PCB test pad portion includes a first PCB pad overlapping the 2nd-1 transmission pad, a second PCB pad overlapping the 2nd-2 transmission pad, and a third PCB pad overlapping the 2nd-3 transmission pad, and
the test terminals include a first input terminal electrically connected to the first PCB pad, a second input terminal electrically connected to the second PCB pad, a first measurement terminal electrically connected to the second PCB pad, and a second measurement terminal electrically connected to the third PCB pad.

12. The display apparatus of claim 11, wherein, when a test current is applied to the first input terminal, the test current flows through a current path including the first PCB pad, the first panel pad, the second panel pad, and the second PCB pad.

13. The display apparatus of claim 11, wherein the panel test pad portion further includes a third panel pad electrically connected to the first panel pad and the second panel pad,
the PCB test pad portion further includes a fourth PCB pad electrically connected to the third panel pad, and
the test terminals further include a third measurement terminal electrically connected to the fourth PCB pad.

14. A display apparatus comprising:
a display panel including a first panel test pad portion and a second panel test pad portion;
a printed circuit board including a first printed circuit board (PCB) test pad portion, a second PCB test pad portion, and test terminals; and
a first flexible circuit board having one end connected to the first panel test pad portion and an opposite end connected to the first PCB test pad portion and a second flexible circuit board having one end connected to the second panel test pad portion and an opposite end connected to the second PCB test pad portion,
wherein each of the first PCB test pad portion and the second PCB test pad portion includes a first PCB pad group and a second PCB pad group,
each of the first PCB pad group and the second PCB pad group includes a first PCB pad, a second PCB pad, a third PCB pad, and a fourth PCB pad, and
the test terminals include a first input terminal electrically connected to the first PCB pad of the first PCB pad group of the first PCB test pad portion, a second input terminal electrically connected to the first PCB pad of the second PCB pad group of the second PCB test pad portion, a first measurement terminal portion electrically connected to the first PCB test pad portion, and a second measurement terminal portion electrically connected to the second PCB test pad portion,
wherein each of the first measurement terminal portion and the second measurement terminal portion includes a 1st-1 measurement terminal electrically connected to the second PCB pad of the first PCB pad group, a 2nd-1 measurement terminal electrically connected to the third PCB pad of the first PCB pad group, a 3rd-1 measurement terminal electrically connected to the fourth PCB pad of the first PCB pad group, a 1st-2 measurement terminal electrically connected to the second PCB pad of the second PCB pad group, a 2nd-2 measurement terminal electrically connected to the third PCB pad of the second PCB pad group, and a 3rd-2 measurement terminal electrically connected to the fourth PCB pad of the second PCB pad group.

15. The display apparatus of claim 14, wherein the second PCB pad of the first PCB pad group of the first PCB test pad portion is electrically connected to the second PCB pad of the second PCB pad group of the first PCB test pad portion,
the first PCB pad of the first PCB pad group of the second PCB test pad portion is electrically connected to the first PCB pad of the second PCB pad group of the first PCB test pad portion, and
the second PCB pad of the first PCB pad group of the second PCB test pad portion is electrically connected to the second PCB pad of the second PCB pad group of the second PCB test pad portion.

16. The display apparatus of claim 14, wherein the first panel test pad portion includes a first panel pad, a second panel pad, and a third panel pad,
the first PCB pad of the first PCB pad group of the first PCB test pad portion is electrically connected to the first panel pad,
the second PCB pad of the first PCB pad group of the first PCB test pad portion is electrically connected to the second panel pad,
the third PCB pad of the first PCB pad group of the first PCB test pad portion is electrically connected to the second panel pad, and
the fourth PCB pad of the first PCB pad group of the first PCB test pad portion is electrically connected to the third panel pad.

17. The display apparatus of claim 16, wherein, when a test current is applied to the first input terminal, the test current flows through a current path including the first PCB pad of the first PCB pad group of the first PCB test pad portion, the first panel pad, the second panel pad, and the second PCB pad of the first PCB pad group of the first PCB test pad portion.

18. The display apparatus of claim 16, wherein the first flexible circuit board includes a first transmission pad portion connected to the first panel test pad portion and a second transmission pad portion connected to the first PCB test pad portion,
wherein the first transmission pad portion includes a 1st-1 transmission pad overlapping the first panel pad, a 1st-2 transmission pad overlapping the second panel pad, and a 1st-3 transmission pad overlapping the third panel pad, and
the second transmission pad portion includes a 2nd-1 transmission pad, a 2nd-2 transmission pad, a 2nd-3 transmission pad, and a 2nd-4 transmission pad, which respectively overlap the first PCB pad, the second PCB pad, the third PCB pad, and the fourth PCB pad of the first PCB pad group of the first PCB test pad portion,
wherein the 1st-1 transmission pad and the 2nd-1 transmission pad are electrically connected to each other by a first wiring line, the 1st-2 transmission pad and the 2nd-2 transmission pad are electrically connected to each other by a second wiring line, the 1st-2 transmission pad and the 2nd-3 transmission pad are electrically connected to each other by the second wiring line and a sub-wiring line connected to the second wiring line, and the 1st-3 transmission pad and the 2nd-4 transmission pad are electrically connected to each other by a third wiring line.

19. The display apparatus of claim 16, further comprising an integrated circuit chip including an integrated circuit (IC) test pad portion,
wherein the display panel further includes an IC transmission pad portion electrically connected to the IC test pad portion, and the IC test pad portion includes a first IC test pad, a second IC test pad, and a third IC test pad,
wherein the first IC test pad is electrically connected to the first panel pad, and the second IC test pad is electrically connected to the second panel pad.

20. The display apparatus of claim 19, wherein, when a test current is applied to the first input terminal, the test current flows through a current path including the first PCB pad of the first PCB pad group of the first PCB test pad portion, the first panel pad, the first IC test pad, the second IC test pad, the second panel pad, and the second PCB pad of the first PCB pad group of the first PCB test pad portion.

21. An electronic device comprising:
a display apparatus; and
a housing accommodating the display apparatus,
wherein the display apparatus comprises:
a display panel including a panel test pad portion;
a printed circuit board including a printed circuit board (PCB) test pad portion and test terminals; and
a flexible circuit board including a first transmission pad portion electrically connected to the panel test pad portion and a second transmission pad portion electrically connected to the PCB test pad portion,
wherein the panel test pad portion includes a first panel pad, a second panel pad, and a third panel pad,
the PCB test pad portion includes a first PCB pad electrically connected to the first panel pad, a second PCB pad electrically connected to the second panel pad, a third PCB pad electrically connected to the second panel pad, and a fourth PCB pad electrically connected to the third panel pad, and
the test terminals include a first input terminal electrically connected to the first PCB pad, a second input terminal electrically connected to the second PCB pad, a first measurement terminal electrically connected to the second PCB pad, a second measurement terminal electrically connected to the third PCB pad, and a third measurement terminal electrically connected to the fourth PCB pad.
